(19) United States
(12) Patent Application Publication
(10) Pub. No.: US 2026/0206313 A1
(43) Pub. Date: Jul. 16, 2026

(54) SYSTEMS AND METHODS FOR POROUS BACKSIDE CONTACTS

(71) Applicant: IQE plc, St. Mellons, Cardiff (GB)

(72) Inventor: Richard HAMMOND, St. Mellons, Cardiff (GB)

(21) Appl. No.: 19/135,465

(22) PCT Filed: Dec. 6, 2023
(86) PCT No.: PCT/EP2023/084574

§ 371 Date: Jun. 4, 2025

(30) Foreign Application Priority Data
Dec. 12, 2022 (GB) 2218644.9

(51) Int. Cl. H10D 86/00; H10P 90/00

(52) U.S. Cl. CPC H10D 86/201; H10P 90/1906

(57) ABSTRACT

A layered structure includes a conductive layer coupled to a backside of a substrate, and a porous layer over the substrate. The conductive layer has a lower resistivity than the substrate. The porous layer has a higher resistivity than the substrate. Advantageously the backside conductive layer can improve current conduction through the substrate during electrochemical etching, improve a thickness uniformity of the porous layer, reduce a charge transfer depletion region width on the backside of the substrate, and reduce metal contamination in the layered structure.

### BACKGROUND

### Field

The present disclosure relates to porous apparatuses, systems, and methods, for example, porous apparatuses, systems, and methods for forming porous backside contacts to improve current conduction during electrochemical etching, reduce a charge transfer depletion region width, and reduce metal contamination.

### Background

Semiconductor-on-insulator (SOI) structures are commonly employed to realize radio frequency (RF) designs where low signal leakage is required. These SOI structures use a buried oxide (BOX) under a top device layer in which RF circuit components, such as transistors and/or passive components, can be fabricated. A handle wafer functioning as a substrate under the BOX can result in signal leakage due to RF fringing fields penetrating into the substrate.

Current incumbent RF-SOI technology utilizes a trap-rich SOI to reduce carrier accumulation due to RF fringing fields and improve harmonic losses. A trap-rich layer (e.g., polysilicon) is formed between the handle wafer and the BOX to minimize parasitic surface conduction effects that can adversely affect RF devices in the top device layer. In addition, to further improve substrate harmonic losses, high resistivity handle wafers (e.g., greater than 3,000 Ω·cm) are used to reduce the amount of free charge carriers. However, this approach requires costly and/or specialized fabrication techniques.

Porous semiconductors are an alternative to SOI substrates. Porous semiconductors can achieve high resistivity properties on a standard CMOS silicon wafer, rather than a high resistivity SOI wafer. Porosification can form a porous region with a particular thickness and porosity in a layer or substrate. For example, electrochemically etching a standard low resistivity (e.g., 1 Ω·cm) silicon wafer can form a thick (e.g., greater than 10 microns) porous silicon surface layer. The porous etch can deplete free charge carriers within the silicon and increase a resistivity of the porous silicon layer by several orders of magnitude (e.g., from 1 Ω·cm to greater than 5,000 Ω·cm). The high resistivity and low relative permittivity (e.g., about 2.2) of porous silicon can suppress harmonic losses by several orders of magnitude more than trap-rich SOI.

Further, porous silicon provides an epitaxy platform to regrow a defect-free, single crystal silicon epilayer. Epitaxy refers to crystal growth or material deposition in which new crystalline layers are formed with one or more well-defined orientations. Epitaxy can be used to grow high quality, single crystal semiconductors atop the porous layer. For example, such an epilayer can be used as a device layer for RF circuit components (e.g., an RF CMOS switch).

However, during porosification, a heavily doped backside contact (e.g., 0.01 Ω·cm) is needed to pass an anodizing (etching) current through a low resistivity wafer (e.g., 1 Ω·cm) to form the porous layer. Further, growing a thick epitaxial layer (e.g., greater than 10 microns) on a heavily doped handle (backside) wafer (e.g., 0.01 Ω·cm) can be costly and time-consuming. In addition, backside metal contacts on the wafer during porosification can lead to metal contamination in the substrate and the porous layer.

### SUMMARY

Accordingly, there is a need to utilize porous backside contacts during porosification of a low resistivity wafer (e.g., 1 Ω·cm) to simultaneously improve current flow through the wafer during electrochemical (EC) etching, improve a thickness uniformity of a porous layer, reduce a charge transfer depletion region width in the wafer, reduce metal contamination, and utilize batch processing to improve manufacturing efficiency.

In some aspects, a layered structure can include a conductive layer coupled to a backside of a substrate, and a porous layer over the substrate. In some aspects, the conductive layer has a lower resistivity than the substrate. In some aspects, the porous layer has a higher resistivity than the substrate. Advantageously the conductive layer coupled to the substrate can improve current flow through the substrate during EC etching, reduce a charge transfer depletion region width on a backside of the substrate, and reduce metal contamination in the substrate and the porous layer.

In some aspects, a resistivity of the substrate is between about 0.1 Ω·cm and about 10 Ω·cm. In some aspects, a resistivity of the substrate is at least about 1 Ω·cm. In some aspects, the substrate includes a Group IV semiconductor. In some aspects, the substrate includes silicon. In some aspects, the substrate includes silicon carbide. In some aspects, the substrate includes a Group III-V semiconductor. In some aspects, the substrate includes gallium arsenide. In some aspects, the substrate includes gallium nitride. Advantageously the low resistivity substrate can form a high resistivity porous layer (e.g., greater than 5,000 Ω·cm) and avoids using a costly and time-consuming heavily doped handle (backside) wafer (e.g., 0.01 Ω·cm).

In some aspects, a resistivity of the conductive layer is between about 0.001 Ω·cm and about 0.1 Ω·cm. In some aspects, a resistivity of the conductive layer is no greater than about 0.01 Ω·cm. In some aspects, the conductive layer has a p-type dopant concentration of at least about 1×10¹⁷ cm⁻³. In some aspects, the conductive layer includes heavily doped polycrystalline silicon. Advantageously the high resistivity conductive layer improves current flow through the substrate during EC etching, reduces a charge transfer depletion region width on a backside of the substrate, and reduces metal contamination in the porous layer.

In some aspects, the porous layer includes a first porous sublayer on the substrate and a second porous sublayer on the first porous sublayer. In some aspects, the first porous sublayer has a first porosity and the second porous sublayer has a second porosity that is less than the first porosity. Advantageously the lower porosity second porous sublayer can act as a seed layer for subsequent epitaxy atop the second porous sublayer.

In some aspects, the porous layer has a thickness of at least 2 microns. In some aspects, the porous layer has a thickness of at least 5 microns. Advantageously the thick porous layer can have a high resistivity (e.g., greater than 5,000 Ω·cm) thereby suppress harmonic losses of a semiconductor device.

In some aspects, the layered structure can further include a device on or in the porous layer. In some aspects, the layered structure can further include a passive device on or in the porous layer. The device may be an inductor or a filter. Advantageously the layered structure provides electrical insulation and thermal conductivity for the device.

In some aspects, the layered structure can further include an epitaxial layer grown directly over the porous layer. In some aspects, the layered structure can further include a semiconductor device in the epitaxial layer. Advantageously the backside conductive layer can increase a quality of the epitaxial layer and decrease contamination in the layered structure.

In some aspects, a method can include forming a conductive layer coupled to a backside of a substrate, and forming a porous layer over at least a portion of the substrate. In some aspects, the conductive layer has a lower resistivity than the substrate. In some aspects, the porous layer has a higher resistivity than the substrate. Advantageously the method can improve current flow through the substrate during EC etching, reduce a charge transfer depletion region width on a backside of the substrate, and reduce metal contamination in the substrate and the porous layer.

In some aspects, a resistivity of the substrate is at least about 1 Ω·cm, a resistivity of the conductive layer is no greater than about 0.01 Ω·cm, and a resistivity of the porous layer is at least about 5,000 Ω·cm. Advantageously the increasing resistivity gradient from conductive layer to substrate and substrate to porous layer avoids using a costly and time-consuming heavily doped handle (backside) wafer (e.g., 0.01 Ω·cm), reduces a charge transfer depletion region width on a backside of the substrate, reduces metal contamination in the porous layer, and suppresses harmonic losses of a semiconductor device.

In some aspects, forming the conductive layer includes ion implanting a dopant into the backside of the substrate. In some aspects, the dopant can be a p-type dopant (e.g., boron). In some aspects, the dopant can be an n-type dopant (e.g., phosphorus). Advantageously ion implanting can efficiently and controllably form a conductive layer (e.g., p+ or n+) in the substrate to improve current flow through the substrate during EC etching, reduce a charge transfer depletion region width on a backside of the substrate, and reduce metal contamination in the substrate and the porous layer.

In some aspects, forming the conductive layer includes epitaxially growing a doped layer on the backside of the substrate. In some aspects, the doped layer can include p-type dopants (e.g., boron). In some aspects, the doped layer can include n-type dopants (e.g., phosphorus). Advantageously, epitaxial growth can efficiently and controllably form a conductive layer (e.g., p+ or n+) on the substrate to improve current flow through the substrate during EC etching, reduce a charge transfer depletion region width on a backside of the substrate, and reduce metal contamination in the porous layer.

In some aspects, forming the conductive layer includes diffusing dopants from a doped glass into the backside of the substrate. In some aspects, the doped glass can include p-type dopants (e.g., borosilicate glass (BSG) with boron dopants). In some aspects, the doped glass can include n-type dopants (e.g., phosphosilicate glass (PSG) with phosphorus dopants). Advantageously depositing doped glass and subsequently diffusing dopants from the doped glass into the substrate can efficiently and controllably form a conductive layer (e.g., p+ or n+) in the substrate to improve current flow through the substrate during EC etching, reduce a charge transfer depletion region width on a backside of the substrate, and reduce metal contamination in the substrate and the porous layer.

In some aspects, the substrate is a single side polished (SSP) wafer and forming the conductive layer includes forming heavily doped polycrystalline silicon (poly-Si). Advantageously, during epitaxy, a single crystal epilayer and the heavily doped poly-Si can be simultaneously grown on the frontside and the backside of the SSP wafer, respectively.

In some aspects, the method can further include forming a second conductive layer coupled to a frontside of the substrate, the second conductive layer having a lower resistivity than the substrate. Advantageously the second conductive layer can act as a seed layer for subsequent epitaxy atop the porous layer.

In some aspects, forming the conductive layer and forming the second conductive layer includes simultaneously epitaxially growing doped layers on the backside and the frontside of the substrate. In some aspects, the doped layers can include p-type dopants (e.g., boron). In some aspects, the doped layers can include n-type dopants (e.g., phosphorus). In some aspects, the substrate is a double side polished (DSP) wafer and forming the conductive layer and forming the second conductive layer includes simultaneously epitaxially growing doped layers (e.g., p-type) on the backside and the frontside of the substrate. Advantageously, during epitaxy, first and second doped epilayers can be simultaneously grown on the frontside and the backside of the wafer (e.g., DSP wafer), respectively, to improve manufacturing efficiency.

In some aspects, the method can further include batch processing a plurality of substrates (e.g., twenty-five DSP wafers, fifty DSP wafers, a hundred DSP wafers, etc.) to simultaneously epitaxially grow doped layers (e.g., p-type) on the backside and the frontside of each of the plurality of substrates. In some aspects, the method can further include batch processing a plurality of substrates (e.g., twenty-five SSP wafers, fifty SSP wafers, a hundred SSP wafers, etc.) to simultaneously epitaxially grow a single crystal epilayer on the frontside (polished) and a heavily doped poly-Si on the backside of each of the plurality of substrates. In some aspects, the batch processing includes processing the plurality of substrates in a hot wall barrel reactor. Advantageously batch processing can improve manufacturing efficiency, improve manufacturing yield, and improve uniformity of fabricated layered structures.

In some aspects, forming the conductive layer and forming the second conductive layer includes simultaneously depositing doped glass layers on the backside and the frontside of the substrate. In some aspects, the doped glass layers can include p-type dopants (e.g., boron). In some aspects, the doped glass layers can include n-type dopants (e.g., phosphorus). In some aspects, forming the conductive layer and forming the second conductive layer further includes annealing the substrate thereby diffusing dopants (e.g., p-type) from the doped glass layers into the substrate. In some aspects, forming the conductive layer and forming the second conductive layer further includes removing (e.g., etching) the doped glass layers. In some aspects, the substrate is a DSP wafer and forming the conductive layer and forming the second conductive layer includes simultaneously depositing doped glass layers (e.g., p-type) on the backside and the frontside of the substrate. In some aspects, the substrate is a SSP wafer and forming the conductive layer and forming the second conductive layer includes simultaneously depositing doped glass layers (e.g., p-type) on the backside and the frontside of the substrate, thereby resulting in a frontside doped epilayer and a backside heavily doped poly-Si layer. Advantageously, during deposition (e.g., CVD), first and second doped glass layers (e.g., BSG, PSG) can be simultaneously grown on the frontside and the backside of the wafer (e.g., DSP wafer), respectively, to improve manufacturing efficiency.

In some aspects, the method can further include batch diffusion processing a plurality of substrates (e.g., twenty-five DSP wafers, fifty DSP wafers, a hundred DSP wafers, twenty-five SSP wafers, fifty SSP wafers, a hundred SSP wafers, etc.) to simultaneously deposit doped glass layers (e.g., p-type) on the backside and the frontside of each of the plurality of substrates. In some aspects, the batch diffusion processing includes processing the plurality of substrates in a tube furnace (e.g., a quartz tube furnace). Advantageously batch diffusion processing can improve manufacturing efficiency, improve manufacturing yield, and improve uniformity of fabricated layered structures.

In some aspects, forming the porous layer includes porosifying the second conductive layer and an upper portion of the substrate. Advantageously the second conductive layer can act as a seed layer for subsequent epitaxy atop the porous layer.

In some aspects, the layered structure can further include a device on or in the porous layer. In some aspects, the layered structure can further include a passive device on or in the porous layer. The device may be an inductor or a filter. Advantageously the layered structure provides electrical insulation and thermal conductivity for the device.

In some aspects, the method can further include growing an epitaxial layer directly over the porous layer. In some aspects, the method can further include annealing the porous layer prior to growing the epitaxial layer. In some aspects, the method can further include forming a semiconductor device in the epitaxial layer. Advantageously the method can improve a quality of the epitaxial layer and improve manufacturing yield.

Implementations of any of the techniques described above can include a system, a method, a process, a device, and/or an apparatus. The details of one or more implementations are set forth in the accompanying drawings and the description below. Other features will be apparent from the description and drawings, and from the claims.

Further features and exemplary aspects of the aspects, as well as the structure and operation of various aspects, are described in detail below with reference to the accompanying drawings. It is noted that the aspects are not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the aspects and, together with the description, further serve to explain the principles of the aspects and to enable a person skilled in the relevant art(s) to make and use the aspects.

FIG. 1 is a schematic cross-sectional illustration of a previously known trap-rich SOI layered structure.

FIG. 2 is a schematic cross-sectional illustration of a porosification system, according to an exemplary aspect.

FIG. 3A is a schematic cross-sectional illustration of a porous layered structure, according to an exemplary aspect.

FIG. 3B is a schematic cross-sectional illustration of a porous layered structure, according to an exemplary aspect.

FIG. 4 is a schematic circuit diagram of a transceiver including an RF switch employing stacked transistors, according to an exemplary aspect.

FIG. 5 is a schematic cross-sectional illustration of a dual bath porosification system, according to an exemplary aspect.

FIG. 6 is a schematic perspective illustration of an ion implantation process into a backside of a substrate, according to an exemplary aspect.

FIG. 7 is a schematic perspective illustration of an epitaxial growth process on a frontside and a backside of a substrate, according to an exemplary aspect.

FIG. 8 is a schematic perspective illustration of a batch process of the epitaxial growth process shown in FIG. 7 for a plurality of substrates, according to an exemplary aspect.

FIG. 9 is a schematic perspective illustration of a diffusion process into a backside of a substrate, according to an exemplary aspect.

FIG. 10 is a schematic perspective illustration of a diffusion process into a frontside and a backside of a substrate, according to an exemplary aspect.

FIG. 11 is a schematic perspective illustration of a batch diffusion process of the diffusion process shown in FIG. 10 for a plurality of substrates, according to an exemplary aspect FIG. 12 is a schematic cross-sectional illustration of a porous layered structure formed from the ion implantation process shown in FIG. 6, according to an exemplary aspect.

FIG. 13 is a schematic cross-sectional illustration of a porous layered structure formed from the epitaxial growth process shown in FIG. 7, according to an exemplary aspect.

FIG. 14 is a schematic cross-sectional illustration of a porous layered structure formed from the diffusion process shown in FIG. 9, according to an exemplary aspect.

FIG. 15 is a schematic cross-sectional illustration of a porous layered structure formed from the diffusion process shown in FIG. 10, according to an exemplary aspect.

FIG. 16 is a schematic manufacturing diagram for forming the porous layered structure shown in FIG. 12, according to an exemplary aspect.

FIG. 17 is a schematic manufacturing diagram for forming the porous layered structure shown in FIG. 13, according to an exemplary aspect.

FIG. 18 is a schematic manufacturing diagram for forming the porous layered structure shown in FIG. 14, according to an exemplary aspect.

FIG. 19 is a schematic manufacturing diagram for forming the porous layered structure shown in FIG. 15, according to an exemplary aspect.

FIG. 20 is a flow diagram for forming the porous layered structure shown in FIG. 12, according to an exemplary aspect.

FIG. 21 is a flow diagram for forming the porous layered structure shown in FIG. 13, according to an exemplary aspect.

FIG. 22 is a flow diagram for forming the porous layered structure shown in FIG. 14, according to an exemplary aspect.

FIG. 23 is a flow diagram for forming the porous layered structure shown in FIG. 15, according to an exemplary aspect.

The features and exemplary aspects of the aspects will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more aspects that incorporate the features of this present invention. The disclosed aspect(s) merely exemplify the present invention. The scope of the invention is not limited to the disclosed aspect(s). The present invention is defined by the claims appended hereto.

The aspect(s) described, and references in the specification to “one aspect,” “an aspect,” “an example aspect,” “an exemplary aspect,” etc., indicate that the aspect(s) described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of one skilled in the art to affect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The term “about” or “substantially” or “approximately” as used herein means the value of a given quantity that can vary based on a particular technology. Based on the particular technology, the term “about” or “substantially” or “approximately” can indicate a value of a given quantity that varies within, for example, 0.1-10% of the value (e.g., ±0.1%, ±1%, +2%, ±5%, or ±10% of the value).

The term “epitaxy” or “epitaxial” as used herein means crystalline growth of material, for example, via high temperature deposition. Epitaxy can be effected in a molecular beam epitaxy (MBE) tool in which layers are grown on a heated substrate in an ultra-high vacuum environment. Elemental sources are heated in furnaces and directed towards the substrate without carrier gases. The elemental constituents react at the substrate surface to create a deposited layer.

Epitaxy can also be performed in a vapor phase epitaxy (VPE) tool, also known as a chemical vapor deposition (CVD) tool. CVD is the formation of stable solids by decomposition of gaseous chemicals using heat, plasma, ultraviolet, or other energy sources. Silicon epitaxy can be produced by CVD using heat as the energy source to decompose gaseous chemicals. For example, silicon and dopant atoms can be brought to a single crystal surface by gaseous transport to form a doped epitaxial layer. The CVD tool can be controlled by reactor design variables and operator variables, each of which can influence the uniformity, productivity, and quality of the epitaxial layer.

Epitaxy can also be performed in a metal-organic vapor phase epitaxy (MOVPE) tool, also known as a metal-organic chemical vapor deposition (MOCVD) tool. Compound metal-organic and hydride sources flow over a heated surface using a carrier gas, for example, hydrogen. Epitaxial deposition in the MOCVD tool occurs at higher pressures than in an MBE tool. The compound constituents are cracked in the gas phase and then reacted at the surface to grow layers of desired composition.

The term “compound semiconductor material” or “Group III-V semiconductor” or “III-V semiconductor” or “III-V material” as used herein means including one or more materials from Group III of the periodic table (e.g., group 13 elements: boron (B), aluminum (Al), gallium (Ga), indium (In), thallium (Tl)) with one or more materials from Group V of the periodic table (e.g., group 15 elements: nitrogen (N), phosphorus (P), arsenic (As), antimony (Sb), bismuth (Bi)). The compounds have a 1:1 combination of Group III and Group V regardless of the number of elements from each group. Subscripts in chemical symbols of compounds refer to the proportion of that element within that group. For example, Al_{0.25}GaAs means the Group III part comprises 25% Al, and thus 75% Ga, while the Group V part comprises 100% As.

The term “Group IV semiconductor” as used herein indicates comprising one or more materials from Group IV of the periodic table (e.g., group 14 elements: carbon (C), silicon (Si), germanium (Ge), tin (Sn), lead (Pb)). An alloy can be formed from one or more Group IV elements. Subscripts in chemical symbols of the alloy refer to the proportion of that element within the alloy. For example, Si_{0.8}Ge_{0.2} means the alloy comprises 80% Si and 20% Ge.

The term “Group II-VI semiconductor” as used herein indicates comprising one or more materials from Group II of the periodic table (e.g., group 12 elements: zinc (Zn), cadmium (Cd), mercury (Hg)) with one or more materials from Group VI of the periodic table (e.g., group 16 elements: oxygen (O), sulfur (S), selenium (Se), tellurium (Te)).

The term “substrate” as used herein means a planar wafer on which subsequent layers may be deposited, formed, or grown. A substrate may be formed of a single element (e.g., Si) or a compound material (e.g., GaAs), and may be doped or undoped. In some aspects, for example, a substrate can include Si, Ge, GaAs, GaN, GaP, GaSb, InP, InSb, a Group IV semiconductor, a Group III-V semiconductor, a Group II-VI semiconductor, graphene, or silicon carbide (SiC).

A substrate may be on-axis, that is where the growth surface aligns with a crystal plane. For example, a substrate can have <100> crystal orientation. Reference herein to a substrate in a given crystal orientation also encompass a substrate which is miscut by up to about 20° towards another crystallographic direction. For example, a (100) substrate miscut towards the (111) plane.

The term “monolithic” as used herein means a layer or substrate comprising bulk (e.g., single) material throughout. Alternatively, the layer or substrate may be porous for some or all of its thickness.

The term “doping” or “doped” as used herein means that a layer or material contains a small impurity concentration of another element (dopant) which donates (donor) or extracts (acceptor) charge carriers from the parent material and therefore alters the conductivity. Charge carriers may be electrons or holes. A doped material with extra electrons is called n-type while a doped material with extra holes (fewer electrons) is called p-type.

The term “crystalline” as used herein means a material or layer with a single crystal orientation. In epitaxial growth or deposition, subsequent layers with the same or similar lattice constant follow the registry of the previous crystalline layer and therefore grow with the same crystal orientation or crystallinity. As will be understood by a person of ordinary skill in the art, crystal orientation, for example, <100> means the face of cubic crystal structure and encompasses [100], [010], and [001] orientations using the Miller indices. Similarly, for example, <0001> encompasses [0001] and [000-1], except if the material polarity is critical. Also, integer multiples of any one or more of the indices are equivalent to the unitary version of the index. For example, (222) is equivalent to (111).

The term “lattice matched” as used herein means that two crystalline layers have the same, or similar, lattice spacing such that the second layer will tend to grow isomorphically (e.g., same crystalline form) on the first layer, also known as pseudomorphic (e.g., near-lattice-matched).

The term “lattice constant” as used herein means the smallest periodicity of a crystalline lattice along a certain crystal orientation. For example, the unstrained lattice spacing of a crystalline unit cell.

The term “deposition” as used herein means the depositing of a layer on another layer or substrate. Deposition encompasses epitaxy, physical vapor deposition (PVD), electron-beam PVD (EBPVD), sputter deposition, chemical vapor deposition (CVD), plasma-enhanced CVD (PECVD), atomic layer deposition (ALD), powder bed deposition, and/or other known techniques to deposit material in a layer.

The term “lateral” or “in-plane” as used herein means parallel to the surface of the substrate and perpendicular to the growth direction.

The term “vertical” or “out-of-plane” as used herein means perpendicular to the surface of the substrate and in the growth direction.

The term “porosifying” or “porosification” as used herein means forming a porous region with a particular thickness and porosity in a layer or substrate. The porosity of a material is affected by electrolyte concentration, electrolyte current density, electrolyte current fluid velocity, anodization time, temperature, and/or material doping. Porosifying can include electrochemical (EC) etching or photoelectrochemical (PEC) etching to form one or more porous layers in a layer or substrate. For example, an electrolyte current (e.g., hydrofluoric acid (HF) at 100 mA/cm² and 20° C.) can be applied to a layer to form one or more porous layers.

The term “porous region” or “porous layer” as used herein means a layer that includes air or vacuum pores, with the porosity defined as the proportion of the area which is occupied by the pores rather than the bulk (e.g., single) material (e.g., a percentage %). The porosity can vary through the thickness of the layer. For example, the layer may be porous in one or more sublayers. The layer may include an upper portion which is porous and a lower portion that is non-porous. The porosity may be constant or variable within the porous region. Where the porosity is variable, the porosity may be linearly varied through the thickness, or may be varied according to a different function, for example, quadratic, logarithmic, or a step function. Pores in the porous layer can be microporous (e.g., less than 2 nm pore size), mesoporous (e.g., 2 nm to 50 nm pore size), nanoporous (e.g., less than 100 nm pore size), or macroporous (e.g., 50 nm to 1000 nm pore size).

Numerical values, including endpoints of ranges, can be expressed herein as approximations preceded by the term “about,” “substantially,” “approximately,” or the like. In such cases, other aspects include the particular numerical values. Regardless of whether a numerical value is expressed as an approximation, two aspects are included in this disclosure: one expressed as an approximation, and another not expressed as an approximation. It will be further understood that an endpoint of each range is significant both in relation to another endpoint, and independently of another endpoint.

Before describing aspects of the present disclosure in more detail, it is instructive to present exemplary layered structures, porosification systems, and environments in which aspects of the present disclosure may be implemented.

### Exemplary Layered Structures and Porosification Systems

As discussed above, porous semiconductors are an alternative to current incumbent RF-SOI technology that utilize trap-rich SOI substrates. Porosification can form a thick porous region with a particular thickness (e.g., greater than 10 microns) and porosity (e.g., about 35% to 65%) in a layer or substrate, and achieve high resistivity (e.g., greater than 5,000 Ω·cm) on a standard CMOS wafer (e.g., silicon wafer). The high resistivity porous layer (e.g., porous silicon) can suppress harmonic losses by several orders of magnitude more than trap-rich SOI. Further, the porous layer provides an epitaxy platform to regrow a defect-free, single crystal epilayer. For example, such an epilayer can be used as a device layer for RF circuit components (e.g., an RF CMOS switch).

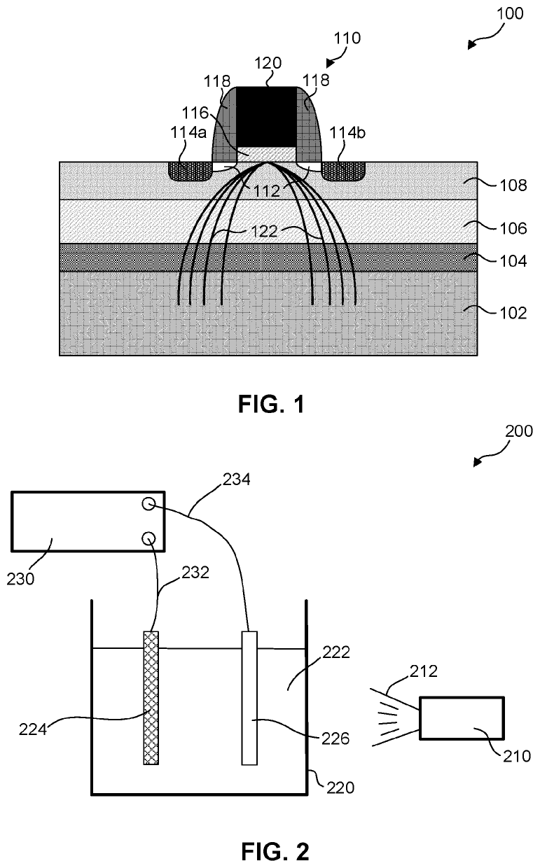

FIG. 1 illustrates trap-rich SOI layered structure 100, according to a previously known configuration. In the example shown in FIG. 1, trap-rich SOI layered structure 100 includes substrate 102 (e.g., silicon), trap-rich layer 104 (e.g., polysilicon), buried oxide (BOX) layer 106 (e.g., silicon dioxide), semiconductor layer 108 (e.g., silicon), and semiconductor device 110 (e.g., MOSFET) in semiconductor layer 108. According to such a configuration, semiconductor device 110 produces RF field lines 122 that penetrate (bleed) through trap-rich layer 104 and BOX layer 106 into substrate 102. This configuration causes significant harmonic losses, crosstalk, and parasitic surface conduction effects.

Semiconductor device 110 can include lightly doped regions 112, source/drain junctions 114a, 114b, gate oxide 116, spacers 118, and gate 120. Lightly doped regions 112 can be implanted with a dopant of a different type (e.g., n-type) than the corresponding semiconductor layer 108 (e.g., p-type). Source/drain junctions 114a, 114b can be implanted with a dopant of the same type as adjacent lightly doped regions 112, but having a higher concentration than lightly doped regions 112. Gate oxide 116 can comprise an electrical insulator, for example, silicon dioxide (SiO₂). Spacers 118 can comprise an electrical insulator, for example, silicon nitride (SiN). Gate 120 can comprise an electrical conductor, for example, polysilicon.

FIG. 2 illustrates porosification system 200, according to an exemplary aspect. Porosification system 200 can be configured to form one or more porous layers in a layer or substrate. In some aspects, porosification system 200 can utilize electrochemical (EC) etching, photoelectrochemical (PEC) etching, or a combination thereof to form one or more porous layers. Although porosification system 200 is shown in FIG. 2 as a stand-alone apparatus and/or system, aspects of this disclosure can be used with other apparatuses, systems, and/or methods.

As shown in FIG. 2, porosification system 200 can include illumination source 210, bath 220, and current source 230. In some aspects, a portion of a layer or substrate (e.g., in-plane or out-of-plane) can be exposed to an electrolyte current such that the portion is etched and a porous region remains. In some aspects, a porosity of the porous region can be controlled by adjusting electrolyte concentration, electrolyte current density, electrolyte current fluid velocity, porosification time, temperature, material doping, illumination power, and/or illumination wavelength. In some aspects, a thickness of the porous region can be controlled by adjusting a porosification (etching) time.

Illumination source 210 is configured to supplement EC etching of a layer or substrate (e.g., substrate 226) in bath 220 with PEC etching to form a porous region in the layer or substrate. PEC etching is dopant and bandgap selective and creates holes at the surface of the layer or substrate. Illumination source 210 can include a UV source (e.g., mercury lamp, arc lamp, etc.) and generate PEC illumination 212 over a portion or all of the layer or substrate. In some aspects, illumination source 210 can be a pulsed light source or include a mechanical modulator (e.g., chopper), an acousto-optical modulator (AOM), or an electro-optical modulator (EOM) to generate pulsed illumination having a particular frequency. In some aspects, illumination source 210 can have a power of about 1 mW to 10 W. In some aspects, illumination source 210 can include an optical filter to apply a particular wavelength(s) to the layer or substrate. In some aspects, illumination source 210 can be omitted for pure EC etching.

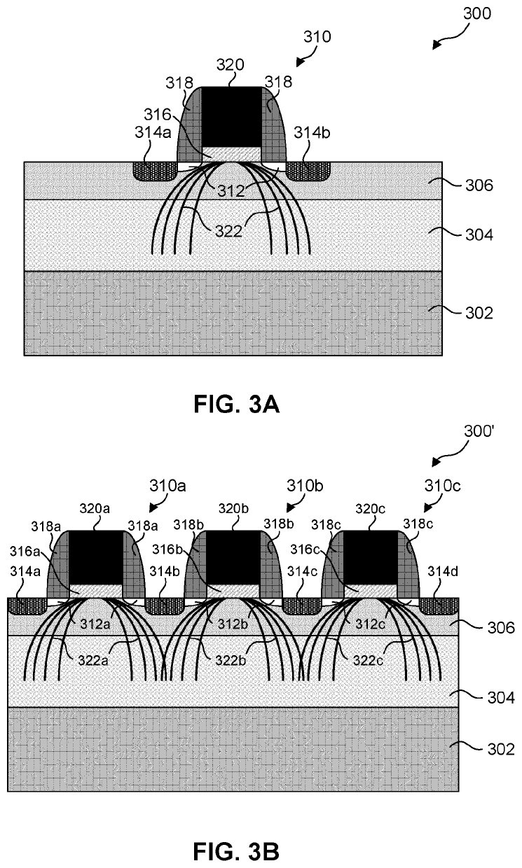

Bath 220 is configured to provide EC etching (e.g., chemical etch) of a layer or substrate (e.g., substrate 226) to form a porous region in the layer or substrate. Bath 220 can include electrolyte 222, electrode 224, and substrate 226 (e.g., substrate 302 shown in FIGS. 3A and 3B). In some aspects, electrolyte 222 can include any material (e.g., acid, alkali, oxidizer, salt, etc.) to facilitate EC etching of substrate 226. For example, electrolyte 222 can include hydrofluoric (HF) acid, buffered HF (5:2), hydrochloric (HCl) acid, hydrobromic (HBr) acid, sulfuric acid (H₂SO₄), nitric acid (HNO₃), oxalic acid (C₂H₂O₄), sodium hydroxide (NaOH), potassium hydroxide (KOH), hydrogen peroxide (H₂O₂), or any other suitable acid, alkali, salt, or oxidizer. Electrode 224 can include any suitable conductor (e.g., metal, copper (Cu), aluminum (Al), platinum (Pt), etc.). In some aspects, bath 220 can maintain a temperature of about 20° C. to about 60° C. In some aspects, substrate 226 can include substrate 302 or a portion (e.g., upper surface) of substrate 302 shown in FIGS. 3A and 3B. In some aspects, substrate 226 can be coupled to a holder such that one side of substrate 226 (e.g., frontside) is exposed to electrolyte 222 during EC etching while the opposite side of the substrate 226 (e.g., backside) is contacted to an electrical contact (e.g., a doped wafer, a metallic plate, etc.) and sealed by the holder so as not to be exposed to electrolyte 222 during EC etching.

Current source 230 is configured to provide EC etching (e.g., current etch) of a layer or substrate (e.g., substrate 226) to form a porous region in the layer or substrate. Current source 230 can include cathode 232 and anode 234. When combined, current source 230 and bath 220 form an electrolyte current. In some aspects, as shown in FIG. 2, cathode 232 can be connected to electrode 224 and anode 234 can be connected to substrate 226 to complete the circuit. When current is applied, substrate 226 is etched (e.g., porosified), with or without illumination source 210, and electron flow is away from substrate 226 towards electrode 224. Electrons resonate at pore tips in substrate 226 and porosity extends through substrate 226. In some aspects, the electrolyte current density is about 1 mA/cm² to about 350 mA/cm² . For example, the electrolyte current density can be about 10 mA/cm² to about 100 mA/cm². In some aspects, the lattice parameter of the starting material (e.g., substrate 226) remains relatively unchanged following the porosification process. In some aspects, a porosification rate in substrate 226 can be about 1 nm/min to about 25 μm/min. For example, the porosification rate can be about 0.1 μm/min to about 5 μm/min.

In some aspects, porosification system 200 can perform a porosification process (e.g., EC etch) on substrate 226 by exposing a portion of substrate 226 (e.g., frontside) to electrolyte 222 (e.g., buffered HF) and applying (passing) an electrolyzing current (e.g., in a range of 5 mA/cm² to 50 mA/cm² ) through substrate 226 from cathode 232 and anode 234 for a specified time (e.g., for 10 seconds to 15 minutes). In some aspects, the porosification process can be carried out in a constant voltage mode (e.g., DC bias of about 5 V to about 25 V) and controlled by monitoring an etching current signal. In some aspects, the porosification process can include oxidation of substrate 226 by localized injection of holes upon application of a positive anodic bias (e.g., anode 234), and localized dissolution of such oxide layer in electrolyte 222 resulting in a porous layer (e.g., porous layer 304 shown in FIGS. 3A and 3B). In some aspects, the porosification process ends when the etching current signal drops to a base line level, indicating that all of the exposed portions of substrate 226 have been porosified and converted into a porous layer (e.g., porous layer 304 shown in FIGS. 3A and 3B).

In some aspects, substrate 226 can comprise any suitable substrate having a predetermined crystallographic orientation, including but not limited to silicon, germanium, gallium nitride (GaN), and III-V semiconductors. In some aspects, substrate 226 can be doped prior to porosification to adjust a resistivity of substrate 226, for example, to a low resistivity in a range of about 0.1 Ω·cm to 10 Ω·cm. In some aspects, electrolyte 222 can include a mixture of HF and deionized water, for example, having a ratio of (5:2) and surfactant (1 ml/l). In some aspects, electrolyte 222 can include a mixture of HF and an alcohol (e.g., ethanol), for example, having a ratio of (5:2).

In some aspects, porosification system 200 can form a porous layer (e.g., porous layer 304 shown in FIGS. 3A and 3B) that provides an epitaxy platform for subsequent regrowth of a defect-free, single crystal epilayer (e.g., epilayer 306 shown in FIGS. 3A and 3B). For example, porosification system 200 can form a porous layer (e.g., porous layer 304 shown in FIGS. 3A and 3B) with a low porosity (e.g., about 35%) such that the porous layer is relatively crystalline and long-range crystallinity of the porous layer is not significantly affected by the porosification process.

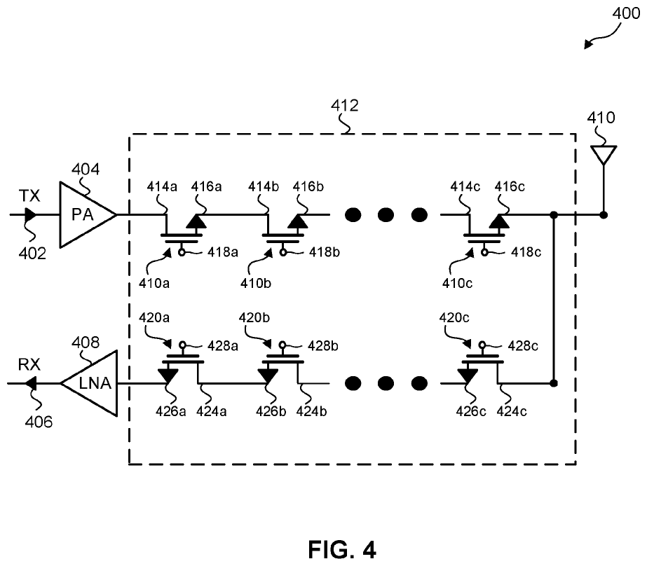

FIGS. 3A and 3B illustrate porous layered structures 300, 300′, according to exemplary aspects. Porous layered structures 300, 300′ can be configured to reduce signal leakage and suppress RF fringing fields (bleeding) into the substrate 302. In some aspects, porous layered structures 300, 300′ can be utilized in an RF device, for example, RF switch 412 shown in FIG. 4. Although porous layered structures 300, 300′ are shown in FIGS. 3A and 3B as stand-alone apparatuses and/or systems, aspects of this disclosure can be used with other apparatuses, systems, and/or methods.

As shown in FIG. 3A, porous layered structure 300 can include substrate 302 (e.g., silicon), porous layer 304 (e.g., porous silicon), epilayer 306 (e.g., single crystal silicon epilayer), and semiconductor device 310 (e.g., MOSFET) in epilayer 306. In some aspects, porous layered structure 300 with high resistivity porous layer 304 (e.g., greater than about 5,000 Ω·cm) prevents RF field lines 322 from semiconductor device 310 from penetrating (bleeding) into substrate 302. In some aspects, porous layered structure 300 suppresses harmonic losses, reduces crosstalk, and reduces parasitic surface conduction effects.

In some aspects, substrate 302 can comprise any suitable substrate having a predetermined crystallographic orientation, including but not limited to silicon, germanium, gallium nitride (GaN), and III-V semiconductors. In some aspects, substrate 302 can be doped prior to porosification to adjust a resistivity of substrate 302, for example, to a low resistivity in a range of about 0.1 Ω·cm to 10 Ω·cm.

In some aspects, porous layer 304 can be a fully depleted porous layer (i.e., free of charge carriers). In some aspects, porous layer 304 can be a porous silicon layer. For example, porous layer 304 can be formed from a silicon substrate. In some aspects, porous layer 304 can have a resistivity greater than about 5,000 Ω·cm. In some aspects, porous layer 304 can have a thickness greater than about 10 microns. In some aspects, porous layer 304 can have a porosity of about 35% to 65%. In some aspects, pores in porous layer 304 can be mesoporous (e.g., 2 nm to 50 nm pore size).

In some aspects, epilayer 306 can be a defect-free, single crystal epilayer formed directly atop porous layer 304. In some aspects, epilayer 306 can comprise any suitable epilayer having a predetermined crystallographic orientation, including but not limited to silicon, germanium, gallium nitride (GaN), and III-V semiconductors. In some aspects, epilayer 306 can have the same crystallographic orientation as substrate 302.

Semiconductor device 310 can include lightly doped regions 312, source/drain junctions 314a, 314b, gate oxide 316, spacers 318, and gate 320. Lightly doped regions 312 can be implanted with a dopant of a different type (e.g., n-type) than the corresponding epilayer 306 (e.g., p-type). Source/drain junctions 314a, 314b can be implanted with a dopant of the same type as adjacent lightly doped regions 312, but having a higher concentration than lightly doped regions 312. Gate oxide 316 can comprise an electrical insulator, for example, SiO₂. Spacers 318 can comprise an electrical insulator, for example, SiN. Gate 320 can comprise an electrical conductor, for example, polysilicon. In some aspects, semiconductor device 310 can be a transistor (e.g., MOSFET) in a CMOS device, for example, an RF switch (e.g., RF switch 412 shown in FIG. 4).

In some aspects the semiconductor device 310 can be formed directly in or on the porous layer 304 and the epilayer 306 be omitted. The semiconductor device 310 is therefore a passive device such as an inductor or filter.

The aspects of porous layered structure 300 shown in FIG. 3A, for example, and the aspects of porous layered structure 300′ shown in FIG. 3B may be similar. Similar reference numbers are used to indicate features of the aspects of porous layered structure 300 shown in FIG. 3A and the similar features of the aspects of porous layered structure 300′ shown in FIG. 3B.

As shown in FIG. 3B, porous layered structure 300′ can include a plurality of semiconductor devices 310a, 310b, 310c in epilayer 306. In some aspects, semiconductor devices 310a, 310b, 310c can be transistors, for example, MOSFETs. In some aspects, as shown in FIG. 3B, source/drain junction 314b can be shared by semiconductor devices 310a, 310b and source/drain junction 314c can be shared by semiconductor devices 310b, 310c. In some aspects, semiconductor devices 310a, 310b, 310c can be utilized in an RF device, for example, RF switch 412 shown in FIG. 4. For example, semiconductor devices 310a, 310b, 310c can generally correspond to transistors 410a, 410b, 410c (or transistors 420a, 420b, 420c) utilized in RF switch 412 shown in FIG. 4.

In some aspects the semiconductor devices 310a, 310b, 310c can be formed directly in or on the porous layer 304 and the epilayer 306 be omitted. The semiconductor devices 310a, 310b, 310c are therefore a passive device such as an inductor or filter.

FIG. 4 illustrates a circuit diagram of a portion of transceiver 400 with RF switch 412, according to an exemplary aspect. RF switch 412 can be configured to switch transceiver 400 between receive and transmit modes. In some aspects, transceiver 400 can be for a wireless communication device. Although transceiver 400 is shown in FIG. 4 as a stand-alone apparatus and/or system, aspects of this disclosure can be used with other apparatuses, systems, and/or methods.

As shown in FIG. 4, transceiver 400 can include transmit input (TX) 402, power amplifier (PA) 404, receive output (RX) 406, low-noise amplifier (LNA) 408, antenna 410, and RF switch 412. RF switch 412 is situated between PA 404 and antenna 410. PA 404 amplifies RF signals transmitted from transmit input 402. The output of PA 404 is coupled to one end of RF switch 412. Another end of RF switch 412 is coupled to antenna 410. Antenna 410 can transmit amplified RF signals. RF switch 412 is also situated between LNA 408 and antenna 410. Antenna 410 also receives RF signals. Antenna 410 is coupled to one end of RF switch 412. Another end of RF switch 412 is coupled to the input of LNA 408. LNA 408 amplifies RF signals received from RF switch 412. Receive output 406 receives amplified RF signals from LNA 408. In some aspects, RF switch 412 can employ stacked transistors.

RF switch 412 can include two stacks of transistors. The first stack includes transistors 410a, 410b, and 410c. Each transistor 410a, 410b, 410c has a corresponding drain 414a, 414b, 414c, source 416a, 416b, 416c, and gate 418a, 418b, 418c. The second stack includes transistors 420a, 420b, and 420c. Each transistor 420a, 420b, 420c has a corresponding drain 424a, 424b, 424c, source 426a, 426b, 426c, and gate 428a, 428b, 428c. When transistors 410a, 410b, and 410c are in OFF states, and transistors 420a, 420b, and 420c are in ON states, transceiver 400 is in receive mode. When transistors 410a, 410b, and 410c are in ON states, and transistors 420a, 420b, and 420c are in OFF states, transceiver 400 is in transmit mode. In some aspects, RF switch 412 can switch transceiver 400 between two transmit modes corresponding to different frequencies, or between two receive modes corresponding to different frequencies. In some aspects, RF switch 412 can be utilized in a semiconductor structure that reduces signal leakage.

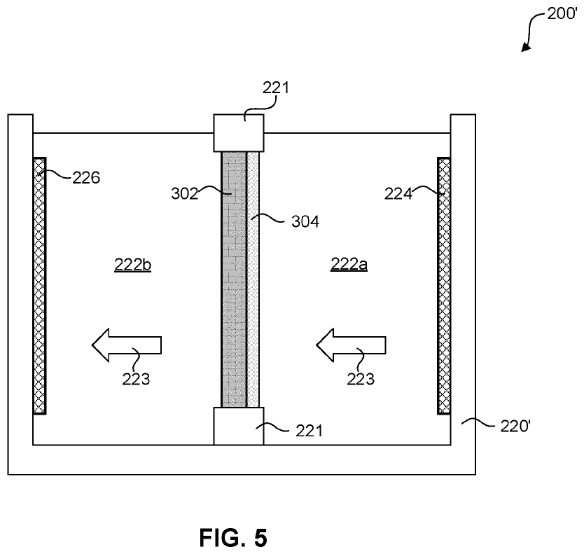

FIG. 5 illustrates dual bath porosification system 200′, according to an exemplary aspect. Dual bath porosification system 200′ can be configured to form one or more porous layers in a layer or substrate. Dual bath porosification system 200′ can be further configured to utilize a liquid backside (anode) contact to the layer or substrate thereby reducing metal contamination in the formed porous layer. Although dual bath porosification system 200′ is shown in FIG. 5 as a stand-alone apparatus and/or system, aspects of this disclosure can be used with other apparatuses, systems, and/or methods, for example, modified substrate 302′, modified substrate 302″, porous layered structure 300″, porous layered structure 300″, manufacturing diagram 1100, manufacturing diagram 1200, flow diagram 1300, and/or flow diagram 1400.

The aspects of porosification system 200 shown in FIG. 2, for example, and the aspects of dual bath porosification system 200′ shown in FIG. 5 may be similar. Similar reference numbers are used to indicate features of the aspects of porosification system 200 shown in FIG. 2 and the similar features of the aspects of dual bath porosification system 200′ shown in FIG. 5.

As shown in FIG. 5, dual bath porosification system 200′ can include dual bath 220′. Dual bath 220′ can be configured to flow current 223 through substrate 302 from cathode 224 to anode 226 to form porous layer 304 on substrate 302. In some aspects, dual bath 220′ can include polytetrafluoroethylene (PTFE), fluoropolymers, or any other acid resistive (e.g., HF acid) material. In some aspects, cathode 224 and anode 226 can include any suitable conductor (e.g., metal, Cu, Al, Pt, etc.). In some aspects, cathode 224 and anode 226 can include a doped semiconductor, for example, doped silicon (e.g., p-type). In some aspects, cathode 224 and anode 226 can include boron-doped diamond (BDD). For example, cathode 224 and anode 226 can each include a silicon wafer coated with BDD. In some aspects, cathode 224 and anode 226 can be connected to a current source (e.g., current source 230 shown in FIG. 2) to form an electrolyte current.

Dual bath 220′ can include substrate holder 221, first electrolyte 222a, and second electrolyte 222b. Substrate holder 221 can be configured to secure substrate 302 in dual bath 220′ during a porosification process. In some aspects, substrate holder 221 can adjust a distance between substrate 302 and cathode 224 and a distance between substrate 302 and anode 226. First electrolyte 222a can be configured to flow current 223 from cathode 224 to substrate 302 during a porosification process (e.g., EC etching). In some aspects, first electrolyte 222a can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, first electrolyte 222a can include buffered HF acid. In some aspects, first electrolyte 222a can have an electrolyte concentration between about 30% to about 50%. For example, first electrolyte 222a can include buffered HF acid having an acid concentration of about 40%.

Second electrolyte 222b can be configured to flow current 223 from substrate 302 to anode 226 during a porosification process (e.g., EC etching). In some aspects, second electrolyte 222b can include HF acid, buffered HF acid, HCl acid, HBr acid, H₂SO₄, HNO₃, C₂H₂O₄, NaOH, KOH, H₂O₂, or any other suitable acid, alkali, salt, or oxidizer. For example, second electrolyte 222b can include buffered HF acid. In some aspects, second electrolyte 222b can include a liquid metal (e.g., mercury (Hg), tin (Sn), cesium (Cs), gallium (Ga), etc.), a metallic solution (e.g., metal nanoparticles in DI water), or any other suitable conductive liquid. For example, second electrolyte 222b can include Hg. In some aspects, second electrolyte 222b can have an electrolyte concentration between about 1% to about 10%. For example, second electrolyte 222b can include buffered HF acid having an acid concentration of about 4%. In some aspects, a ratio of electrolyte concentration of first and second electrolytes 222a, 222b (first:second) can be between about 4 to about 40. For example, the ratio of acid concentration of first and second electrolytes 222a, 222b can be about 10.

### Exemplary Backside Conductive Layers

As discussed above, during porosification, a heavily doped backside contact (e.g., 0.01 Ω·cm) is needed to pass an anodizing (etching) current through a low resistivity wafer (e.g., 1 Ω·cm) to reduce a charge transfer depletion region width on a backside of the substrate and form the porous layer. For example, as shown in FIG. 5, a substrate 302 having a resistivity of about 0.01 Ω·cm can easily pass current 223 through substrate 302, but a substrate 302 having a resistivity of about 1 Ω·cm cannot pass current 223 due to a charge transfer depletion region (region free of all charge carriers) that forms on a backside of substrate 302. Further, growing a thick epitaxial layer (e.g., greater than 10 microns) on a heavily doped handle (backside) wafer (e.g., 0.01 Ω·cm) can be costly and time-consuming. In addition, backside metal contacts on the wafer during porosification can lead to metal contamination (e.g., Al) in the substrate and the porous layer.

Aspects of backside conductive layer apparatuses, systems, and methods as discussed below can simultaneously improve current flow through a substrate during a porosification process, reduce a charge transfer depletion region width in the substrate, reduce metal contamination in the formed porous layer, increase resistivity of the formed porous layer (e.g., greater than 5,000 Ω·cm), and improve manufacturing efficiency through batch processing.

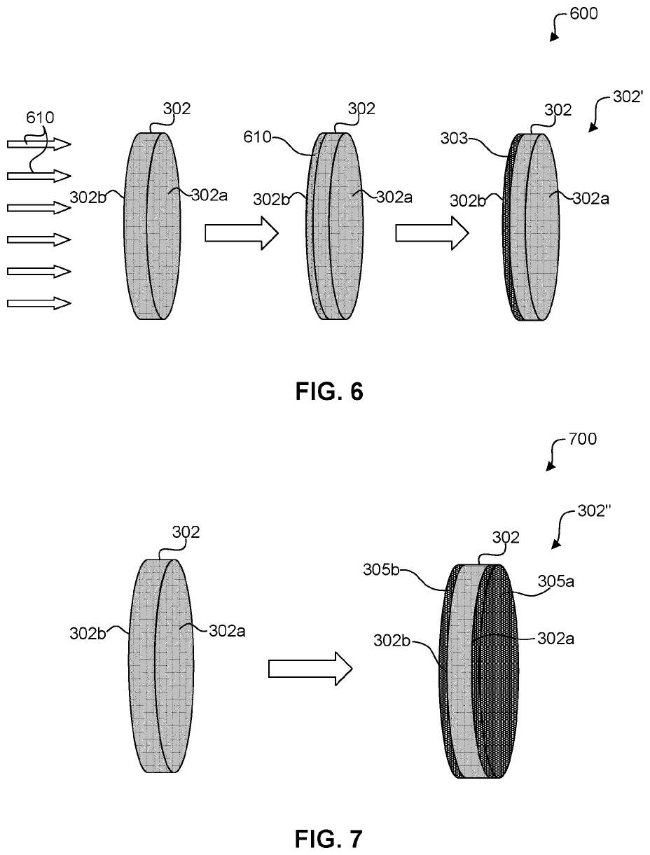

FIGS. 6-11 illustrate modified substrates 302′, 302″, 302″′, 302″″ with backside conductive layers 303, 305b, 303′, 305b′ for porous layered structures 300″, 300″′, 300″″, 300″″′ shown in FIGS. 12-15, respectively, according to exemplary aspects. Modified substrates 302′, 302″, 302″′, 302″″ with backside conductive layers 303, 305b, 303′, 305b′ can be configured to improve current flow through substrate 302, improve a thickness uniformity of porous layers 304, 304′, 304″ reduce a charge transfer depletion region width in substrate 302, and reduce metal contamination in porous layers 304, 304′, 304′ respectively. Although modified substrates 302′, 302″, 302″′, 302″″ are shown in FIGS. 6-11 as stand-alone apparatuses and/or systems, aspects of this disclosure can be used with other apparatuses, systems, and/or methods, for example, dual bath porosification system 200′, porous layered structure 300″, porous layered structure 300″′, porous layered structure 300″″, porous layered structure 300″″′, manufacturing diagram 1600, manufacturing diagram 1700, manufacturing diagram 1800, manufacturing diagram 1900, flow diagram 2000, flow diagram 2100, flow diagram 2200, and/or flow diagram 2300.

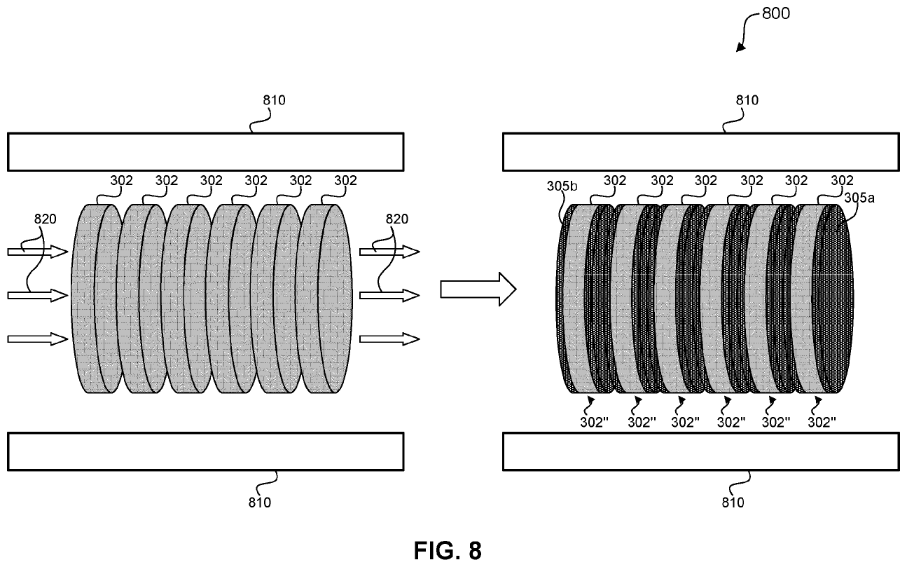

FIG. 6 illustrates ion implantation process 600 to form modified substrate 302′ with backside conductive layer 303, according to an exemplary aspect. Ion implantation process 600 can be configured to form backside conductive layer 303 in substrate 302 to form a heavily doped backside contact (e.g., 0.01 Ω·cm). As shown in FIG. 6, ion implantation process 600 can include high dose dopant implants 610 (e.g., boron (B)) into backside 302b of substrate 302. The resulting ion implantation forms modified substrate 302′ with backside conductive layer 303 in backside 302b of substrate 302. In some aspects, substrate 302 with high dose dopant implants 610 can undergo an annealing process at a temperature of at least 800° C. to electrically activate high dose dopant implants 610, recrystallize backside 302b of substrate 302, and form backside conductive layer 303. In some aspects, high dose dopant implants 610 can include a p-type dopant. For example, high dose dopant implants 610 can include one or more Group III elements, for example, boron (B), aluminum (Al), gallium (Ga), or indium (In). In some aspects, high dose dopant implants 610 can include an n-type dopant. For example, high dose dopant implants 610 can include one or more Group V elements, for example, nitrogen (N), phosphorus (P), arsenic (As), or antimony (Sb). In some aspects, ion implantation process 600 can be conducted in a batch process for a plurality of substrates (e.g., SSP wafers, DSP wafers, etc.) to simultaneously form backside conductive layer 303 in each of the plurality of substrates 302. For example, the batch process can be similar to batch process 800 shown in FIG. 8 to form a plurality of modified substrates 302′ each with backside conductive layer 303.

In some aspects, modified substrate 302′ can be formed by using a spin-on-dopant (SOD) process. For example, backside conductive layer 303 can be formed by spinning the SOD (e.g., a boron SOD) on backside 302b of substrate 302, diffusing the SOD into substrate 302 (e.g., at temperature of at least 850° C.), and subsequently removing a borosilicate glass (BSG) layer formed during diffusion (e.g., deglazing with HF acid).

In some aspects, backside conductive layer 303 can have a lower resistivity than substrate 302. For example, backside conductive layer 303 can have a resistivity of about 0.01 Ω·cm and substrate 302 can have a resistivity of about 1 Ω·cm. In some aspects, substrate 302 can have a resistivity of at least about 1 Ω·cm. For example, substrate 302 can have a resistivity between about 1 Ω·cm to about 50 Ω·cm. In some aspects, substrate 302 can have a resistivity between about 0.1 Ω·cm and about 10 Ω·cm. For example, substrate 302 can have a resistivity of about 5 Ω·cm. In some aspects, substrate 302 can include silicon.

In some aspects, backside conductive layer 303 can have a resistivity no greater than about 0.01 Ω·cm. For example, backside conductive layer 303 can have a resistivity between about 1 mΩ·cm to about 0.01 Ω·cm. In some aspects, backside conductive layer 303 can have a resistivity between about 0.001 Ω·cm and about 0.1 Ω·cm. For example, backside conductive layer 303 can have a resistivity of about 0.005 Ω·cm. In some aspects, backside conductive layer 303 can include a p-type dopant concentration of at least about 1×10¹⁷ cm⁻³. For example, backside conductive layer 303 can have a boron concentration of about 5×10¹⁸ cm⁻³. In some aspects, backside conductive layer 303 can include heavily doped polycrystalline silicon (poly-Si). For example, substrate 302 can include a single side polished (SSP) silicon wafer and high dose dopant implants 610 can include B.

FIG. 7 illustrates epitaxial growth process 700 to form modified substrate 302″ with frontside and backside conductive layers 305a, 305b, according to an exemplary aspect. Epitaxial growth process 700 can be configured to form backside conductive layer 305b on backside 302b of substrate 302 to form a heavily doped backside contact (e.g., 0.01 Ω·cm). Epitaxial growth process 700 can be further configured to form frontside conductive layer 305a on frontside 302a of substrate 302 to form a heavily doped frontside contact (e.g., 0.01 Ω·cm).

As shown in FIG. 7, epitaxial growth process 700 can include simultaneously epitaxially growing frontside and backside conductive layers 305a, 305b on substrate 302. The resulting epitaxial growth forms modified substrate 302″ with backside conductive layer 305b on backside 302b of substrate 302 and frontside conductive layer 305a on frontside 302a of substrate 302. In some aspects, epitaxial growth process 700 can include p-type doping. For example, epitaxial growth process 700 can include B, Al, Ga, or In doping during epitaxial growth of frontside and backside conductive layers 305a, 305b. In some aspects, modified substrate 302″ can undergo an annealing process (e.g., temperature of at least 350° C.) subsequent to forming frontside and backside conductive layers 305a, 305b.

In some aspects, modified substrate 302″ can be formed by using a SOD process. For example, frontside and backside conductive layers 305a, 305b can be formed by spinning the SOD (e.g., a boron SOD) on frontside 302a and backside 302b of substrate 302, diffusing the SOD into substrate 302 (e.g., at temperature of at least 850° C.), and subsequently removing BSG surface layers (e.g., deglazing with HF acid).

In some aspects, backside conductive layer 305b can have a lower resistivity than substrate 302. For example, backside conductive layer 305b can have a resistivity of about 0.01 Ω·cm and substrate 302 can have a resistivity of about 1 Ω·cm. In some aspects, substrate 302 can have a resistivity of at least about 1 Ω·cm. For example, substrate 302 can have a resistivity between about 1 Ω·cm to about 50 Ω·cm. In some aspects, substrate 302 can have a resistivity between about 0.1 Ω·cm and about 10 Ω·cm. For example, substrate 302 can have a resistivity of about 5 Ω·cm. In some aspects, substrate 302 can include silicon.

In some aspects, backside conductive layer 305b can have a resistivity no greater than about 0.01 Ω·cm. For example, backside conductive layer 305b can have a resistivity between about 1 mΩ·cm to about 0.01 Ω·cm. In some aspects, backside conductive layer 305b can have a resistivity between about 0.001 Ω·cm and about 0.1 Ω·cm. For example, backside conductive layer 305b can have a resistivity of about 0.005 Ω·cm. In some aspects, backside conductive layer 305b can include a p-type dopant concentration of at least about 1×10¹⁷ cm⁻³. For example, backside conductive layer 305b can have a boron concentration of about 5×10¹⁸ cm⁻³. In some aspects, backside conductive layer 305b can include heavily doped polycrystalline silicon (poly-Si). For example, substrate 302 can include a SSP silicon wafer and epitaxial growth process 700 can include B doping.

In some aspects, frontside conductive layer 305a can have a lower resistivity than substrate 302. For example, frontside conductive layer 305a can have a resistivity of about 0.01 Ω·cm and substrate 302 can have a resistivity of about 1 Ω·cm. In some aspects, frontside conductive layer 305a can have a resistivity no greater than about 0.01 Ω·cm. For example, frontside conductive layer 305a can have a resistivity between about 1 mΩ·cm to about 0.01 Ω·cm. In some aspects, frontside conductive layer 305a can have a resistivity between about 0.001 Ω·cm and about 0.1 Ω·cm. For example, frontside conductive layer 305a can have a resistivity of about 0.005 Ω·cm. In some aspects, frontside conductive layer 305a can include a p-type dopant concentration of at least about 1×10¹⁷ cm⁻³. For example, frontside conductive layer 305a can have a boron concentration of about 5×10¹⁸ cm⁻³. In some aspects, frontside conductive layer 305a can include heavily doped polycrystalline silicon (poly-Si). For example, substrate 302 can include a double side polished (DSP) silicon wafer and epitaxial growth process 700 can include B doping.

The aspects of epitaxial growth process 700 shown in FIG. 7, for example, and the aspects of batch process 800 shown in FIG. 8 may be similar. Similar reference numbers are used to indicate features of the aspects of epitaxial growth process 700 shown in FIG. 7 and the similar features of the aspects of batch process 800 shown in FIG. 8.

FIG. 8 illustrates batch process 800 to form a plurality of modified substrates 302″ each with frontside and backside conductive layers 305a, 305b, according to an exemplary aspect. Batch process 800 can be configured to simultaneously epitaxially grow frontside and backside conductive layers 305a, 305b on a plurality of substrates 302 (e.g., twenty-five wafers, fifty wafers, a hundred wafers, etc.) to improve manufacturing efficiency and uniformity. Batch process 800 can be further configured to utilize epitaxial growth process 700 shown in FIG. 7.

As shown in FIG. 8, batch process 800 can include hot wall barrel reactor 810 and epitaxy process gases 820. The resulting batch epitaxy process forms modified substrates 302″ for a plurality of substrates 302, each with frontside conductive layer 305a on frontside 302a of substrate 302 and backside conductive layer 305b on backside 302b of substrate 302. In some aspects, hot wall barrel reactor 810 can provide a uniform temperature for the plurality of substrates 302 during epitaxial growth, for example, a temperature of at least 350° C. In some aspects, epitaxy process gases 820 can include p-type dopants. For example, epitaxy process gases 820 can include dopant precursors for B, Al, Ga, or In doping during epitaxial growth of frontside and backside conductive layers 305a, 305b. In some aspects, batch process 800 can include ion implantation process 600 for each of the plurality of substrates 302. In some aspects, batch process 800 can include epitaxial growth process 700 for each of the plurality of substrates 302. In some aspects, batch process 800 can include two or more substrates 302. For example, batch process 800 can include a cassette of substrates 302 (e.g., twenty-five wafers) or a plurality of cassettes (e.g., a hundred wafers).

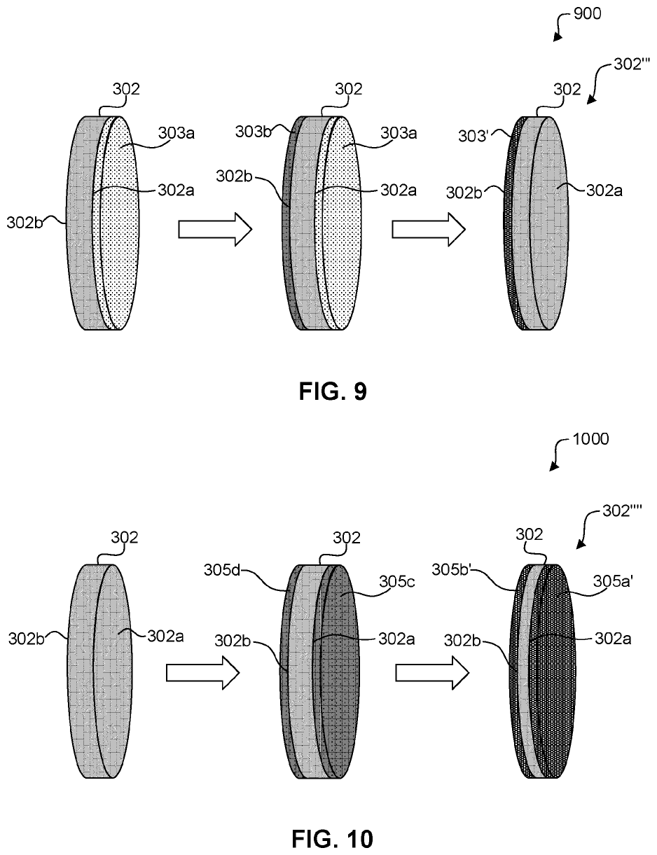

FIG. 9 illustrates diffusion process 900 to form modified substrate 302″′ with backside conductive layer 303′, according to an exemplary aspect. Diffusion process 900 can be configured to form backside conductive layer 303′ in substrate 302 to form a heavily doped backside contact (e.g., 0.01 Ω·cm). As shown in FIG. 9, diffusion process 900 can include forming diffusion blocking layer 303a (e.g., silicon nitride) on frontside 302a of substrate 302, forming doped glass layer 303b (e.g., BSG) on backside 302b of substrate 302, thermally diffusing dopants (e.g., B) of doped glass layer 303b into backside 302b of substrate 302 to form backside conductive layer 303′, and removing diffusion blocking layer 303a and doped glass layer 303b to form modified substrate 302″′. The resulting thermal diffusion and electrical activation of dopants in substrate 302 forms modified substrate 302″′ with backside conductive layer 303′ in backside 302b of substrate 302.

In some aspects, modified substrate 302″′ can include a frontside conductive layer in frontside 302a of substrate 302 rather than backside conductive layer 303′ in backside 302b of substrate 302. For example, diffusion process 900 can be carried out with diffusion blocking layer 303a on backside 302b of substrate 302 rather than frontside 302a and doped glass layer 303b on frontside 302a of substrate 302 rather than backside 302b to form a frontside conductive layer (similar to frontside conductive layer 305a′ shown in FIG. 10).

In some aspects, substrate 302 can undergo an annealing process (e.g., temperature of at least 350° C.) to diffuse dopants of doped glass layer 303b into substrate 302 and form backside conductive layer 303′. For example, substrate 302 with doped glass layer 303b can undergo an annealing process at a temperature of at least 800° C. to thermally diffuse and electrically activate dopants (e.g., B) of doped glass layer 303b into substrate 302, recrystallize backside 302b of substrate 302, and form backside conductive layer 303′. In some aspects, after the annealing process, diffusion blocking layer 303a and doped glass layer 303b can be removed to form modified substrate 302″′. For example, diffusion blocking layer 303a and doped glass layer 303b can be removed by etching (e.g., dry etching, wet etching), for example, by wet etching substrate 302 in HF acid.

In some aspects, doped glass layer 303b can include a p-type dopant. For example, doped glass layer 303b can include borosilicate glass (BSG) with boron dopants. In some aspects, doped glass layer 303b can include a p-type dopant. For example, doped glass layer 303b can include phosphosilicate glass (PSG) with phosphorus dopants. In some aspects, doped glass layer 303b can be formed by deposition (e.g., CVD). In some aspects, diffusion blocking layer 303a can include a nitride or any material sufficient to block diffusion of dopants during an annealing process. For example, diffusion blocking layer 303a can include silicon nitride.

In some aspects, modified substrate 302″′ can be formed by using a SOD process. For example, doped glass layer 303b can be formed by spinning the SOD (e.g., a boron SOD, a phosphorus SOD, phosphorus oxychloride (POCl₃)) on backside 302b of substrate 302, annealing substrate 302 (e.g., at temperature of at least 850° C.) thereby diffusing dopants (e.g., B) of the SOD into substrate 302 to form backside conductive layer 303′ in backside 302b of substrate 302 and forming doped glass layer 303b (e.g., a BSG layer, a PSG layer) on backside 302b of substrate 302, and subsequently removing doped glass layer 303b formed during annealing (e.g., deglazing with HF acid).

In some aspects, backside conductive layer 303′ can have a lower resistivity than substrate 302. For example, backside conductive layer 303′ can have a resistivity of about 0.01 Ω·cm and substrate 302 can have a resistivity of about 1 Ω·cm. In some aspects, backside conductive layer 303′ can have a resistivity no greater than about 0.01 Ω·cm. For example, backside conductive layer 303′ can have a resistivity between about 1 mΩ·cm to about 0.01 Ω·cm. In some aspects, backside conductive layer 303′ can have a resistivity between about 0.001 Ω·cm and about 0.1 Ω·cm. For example, backside conductive layer 303′ can have a resistivity of about 0.005 Ω·cm. In some aspects, backside conductive layer 303′ can include a p-type dopant concentration of at least about 1×10¹⁷ cm⁻³. For example, backside conductive layer 303 can have a boron concentration of about 5×10¹⁸ cm⁻³.

The aspects of diffusion process 900 shown in FIG. 9, for example, and the aspects of diffusion process 1000 shown in FIG. 10 may be similar. Similar reference numbers are used to indicate features of the aspects of diffusion process 900 shown in FIG. 9 and the similar features of the aspects of diffusion process 1000 shown in FIG. 10.

FIG. 10 illustrates diffusion process 1000 to form modified substrate 302″″ with frontside and backside conductive layers 305a′, 305b′, according to an exemplary aspect. Diffusion process 1000 can be configured to form backside conductive layer 305b′ on backside 302b of substrate 302 to form a heavily doped backside contact (e.g., 0.01 Ω·cm). Diffusion process 1000 can be further configured to form frontside conductive layer 305a′ on frontside 302a of substrate 302 to form a heavily doped frontside contact (e.g., 0.01 Ω·cm).

As shown in FIG. 10, diffusion process 1000 can include simultaneously forming frontside and backside doped glass layers 305c, 305d (e.g., BSG, PSG) on substrate 302, thermally diffusing dopants (e.g., B) of frontside and backside doped glass layers 305c, 305d into frontside 302a and backside 302b of substrate 302 to form frontside and backside conductive layers 305a′, 305b′, respectively, and removing frontside and backside doped glass layers 305c, 305d to form modified substrate 302″″. The resulting thermal diffusion and electrical activation of dopants in substrate 302 forms modified substrate 302″″ with frontside conductive layer 305a′ in frontside 302a of substrate 302 and backside conductive layer 305b′ in backside 302b of substrate 302.

In some aspects, substrate 302 can undergo an annealing process (e.g., temperature of at least 350° C.) to diffuse dopants of frontside and backside doped glass layers 305c, 305d into substrate 302 and form frontside and backside conductive layers 305a′, 305b′, respectively. For example, substrate 302 with frontside and backside doped glass layers 305c, 305d can undergo an annealing process at a temperature of at least 800° C. to thermally diffuse and electrically activate dopants (e.g., B) of frontside and backside doped glass layers 305c, 305d into substrate 302, recrystallize frontside 302a and backside 302b of substrate 302, and form frontside and backside conductive layers 305a′, 305b′, respectively. In some aspects, after the annealing process, frontside and backside doped glass layers 305c, 305d can be removed to form modified substrate 302″″. For example, frontside and backside doped glass layers 305c, 305d can be removed by etching (e.g., dry etching, wet etching), for example, by wet etching substrate 302 in HF acid.

In some aspects, frontside and backside doped glass layers 305c, 305d can include a p-type dopant. For example, frontside and backside doped glass layers 305c, 305d can each include BSG with boron dopants. In some aspects, frontside and backside doped glass layers 305c, 305d can include a p-type dopant. For example, frontside and backside doped glass layers 305c, 305d can each include PSG with phosphorus dopants. In some aspects, frontside and backside doped glass layers 305c, 305d can be formed by deposition (e.g., CVD). For example, frontside and backside doped glass layers 305c, 305d can be simultaneously deposited (e.g., CVD) on substrate 302.

In some aspects, modified substrate 302″″ can be formed by using a SOD process. For example, frontside and backside doped glass layers 305c, 305d can be formed by spinning the SOD (e.g., a boron SOD, a phosphorus SOD, POCl₃) on frontside 302a and backside 302b of substrate 302, annealing substrate 302 (e.g., at temperature of at least 850° C.) thereby diffusing dopants (e.g., B) of the SOD into substrate 302 to form frontside and backside conductive layers 305a′, 305b′ in frontside 302a and backside 302b of substrate 302 and forming frontside and backside doped glass layers 305c, 305d (e.g., a BSG layer, a PSG layer) on frontside 302a and backside 302b of substrate 302, respectively, and subsequently removing frontside and backside doped glass layers 305c, 305d formed during annealing (e.g., deglazing with HF acid).

In some aspects, backside conductive layer 305b′ can have a lower resistivity than substrate 302. For example, backside conductive layer 305b′ can have a resistivity of about 0.01 Ω·cm and substrate 302 can have a resistivity of about 1 Ω·cm. In some aspects, backside conductive layer 305b′ can have a resistivity no greater than about 0.01 Ω·cm. For example, backside conductive layer 305b′ can have a resistivity between about 1 mΩ·cm to about 0.01 Ω·cm. In some aspects, backside conductive layer 305b′ can have a resistivity between about 0.001 Ω·cm and about 0.1 Ω·cm. For example, backside conductive layer 305b′ can have a resistivity of about 0.005 Ω·cm. In some aspects, backside conductive layer 305b′ can include a p-type dopant concentration of at least about 1×10¹⁷ cm⁻³. For example, backside conductive layer 305b′ can have a boron concentration of about 5×10¹⁸ cm⁻³.

In some aspects, frontside conductive layer 305a′ can have a lower resistivity than substrate 302. For example, frontside conductive layer 305a′ can have a resistivity of about 0.01 Ω·cm and substrate 302 can have a resistivity of about 1 Ω·cm. In some aspects, frontside conductive layer 305a′ can have a resistivity no greater than about 0.01 Ω·cm. For example, frontside conductive layer 305a′ can have a resistivity between about 1 mΩ·cm to about 0.01 Ω·cm. In some aspects, frontside conductive layer 305a′ can have a resistivity between about 0.001 Ω·cm and about 0.1 Ω·cm. For example, frontside conductive layer 305a′ can have a resistivity of about 0.005 Ω·cm. In some aspects, frontside conductive layer 305a′ can include a p-type dopant concentration of at least about 1×10¹⁷ cm⁻³. For example, frontside conductive layer 305a′ can have a boron concentration of about 5×10¹⁸ cm⁻³.

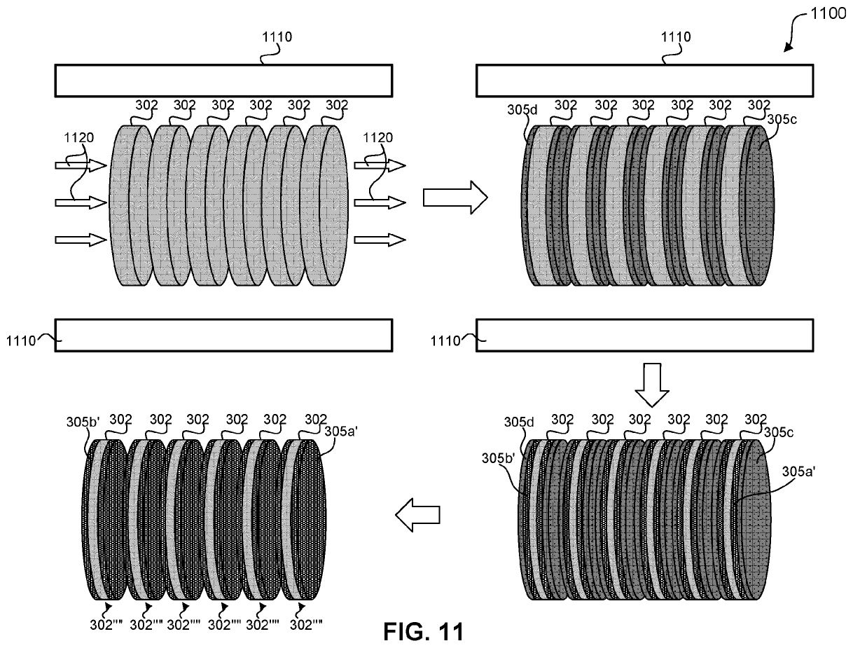

The aspects of diffusion process 1000 shown in FIG. 10, for example, and the aspects of batch diffusion process 1100 shown in FIG. 11 may be similar. Similar reference numbers are used to indicate features of the aspects of diffusion process 1000 shown in FIG. 10 and the similar features of the aspects of batch diffusion process 1100 shown in FIG. 11.

FIG. 11 illustrates batch diffusion process 1100 to form a plurality of modified substrates 302″″ each with frontside and backside conductive layers 305a′, 305b′, according to an exemplary aspect. Batch diffusion process 1100 can be configured to simultaneously form frontside and backside doped glass layers 305c, 305d (e.g., BSG, PSG) on a plurality of substrates 302 (e.g., twenty-five wafers, fifty wafers, a hundred wafers, etc.) to improve manufacturing efficiency and uniformity. Batch diffusion process 1100 can be further configured to utilize diffusion process 1000 shown in FIG. 10. In some aspects, batch diffusion process 1100 can be configured to utilize diffusion process 900 shown in FIG. 9.

As shown in FIG. 11, batch diffusion process 1100 can include tube furnace 1110 and deposition process gases 1120, for example, for CVD formation of frontside and backside doped glass layers 305c, 305d (e.g., BSG, PSG). In some aspects, tube furnace 1110 can include a quartz tube furnace. The resulting batch diffusion process forms modified substrates 302″″ for a plurality of substrates 302, each with frontside conductive layer 305a′ on frontside 302a of substrate 302 and backside conductive layer 305b′ on backside 302b of substrate 302. In some aspects, batch diffusion process 1100 can include simultaneously forming frontside and backside doped glass layers 305c, 305d (e.g., BSG, PSG) on a plurality of substrates 302, thermally diffusing dopants (e.g., B) of frontside and backside doped glass layers 305c, 305d into frontside 302a and backside 302b of each of substrates 302 to form frontside and backside conductive layers 305a′, 305b′, respectively, and removing frontside and backside doped glass layers 305c, 305d to form modified substrates 302″″.

In some aspects, tube furnace 1110 can provide a uniform temperature for the plurality of substrates 302 during formation of frontside and backside doped glass layers 305c, 305d, for example, a temperature of at least 350° C. In some aspects, deposition process gases 1120 can include p-type dopants. For example, deposition process gases 1120 can include precursors (e.g., diborane (B₂H₆), silane (SiH₄)) for forming (e.g., CVD) frontside and backside doped glass layers 305c, 305d (e.g., BSG) on the plurality of substrates 302. In some aspects, deposition process gases 1120 can include n-type dopants. For example, deposition process gases 1120 can include precursors (e.g., trimethylphosphite (P(OCH₃)3), tetraethylorthosilicate (TEOS), oxygen (O₂), POCl₃, phosphine (PH₃), SiH₄) for forming (e.g., CVD) frontside and backside doped glass layers 305c, 305d (e.g., PSG) on the plurality of substrates 302.

In some aspects, batch diffusion process 1100 can include diffusion process 1000 for each of the plurality of substrates 302. In some aspects, batch diffusion process 1100 can include diffusion process 900 for each of the plurality of substrates 302. In some aspects, batch diffusion process 1100 can include a mixture of diffusion process 1000 and diffusion process 900 for the plurality of substrates 302. In some aspects, batch diffusion process 1100 can include two or more substrates 302. For example, batch diffusion process 1100 can include a cassette of substrates 302 (e.g., twenty-five wafers) or a plurality of cassettes (e.g., a hundred wafers).

### Exemplary Porous Layered Structures

FIG. 12 illustrates porous layered structure 300″ with modified substrate 302′ formed from ion implantation process 600 shown in FIG. 6, according to an exemplary aspect. Porous layered structure 300″ can be configured to increase a resistivity of porous layer 304 (e.g., greater than 5,000 Ω·cm) thereby decreasing harmonic losses in semiconductor device 310. Although porous layered structure 300″ is shown in FIG. 12 as a stand-alone apparatus and/or system, aspects of this disclosure can be used with other apparatuses, systems, and/or methods, for example, dual bath porosification system 200′, modified substrate 302′, manufacturing diagram 1600, and/or flow diagram 2000.

The aspects of porous layered structure 300 shown in FIG. 3A, for example, and the aspects of porous layered structure 300″ shown in FIG. 12 may be similar. Similar reference numbers are used to indicate features of the aspects of porous layered structure 300 shown in FIG. 3A and the similar features of the aspects of porous layered structure 300″ shown in FIG. 12.

As shown in FIG. 12, porous layered structure 300″ can include modified substrate 302′ with backside conductive layer 303 and porous layer 304. In some aspects, porous layer 304 can have a higher resistivity than substrate 302. For example, porous layer 304 can have a resistivity of about 1,000 Ω·cm and substrate 302 can have a resistivity of about 1 Ω·cm. In some aspects, porous layer 304 can have a high resistivity (e.g., greater than about 5,000 Ω·cm) thereby decreasing harmonic losses. For example, porous layer 304 can suppress RF field lines from semiconductor device 310 from penetrating (bleeding) into substrate 302. In some aspects, porous layer 304 can have a thickness of at least 5 μm. For example, porous layer 304 can have a thickness of about 10 μm.

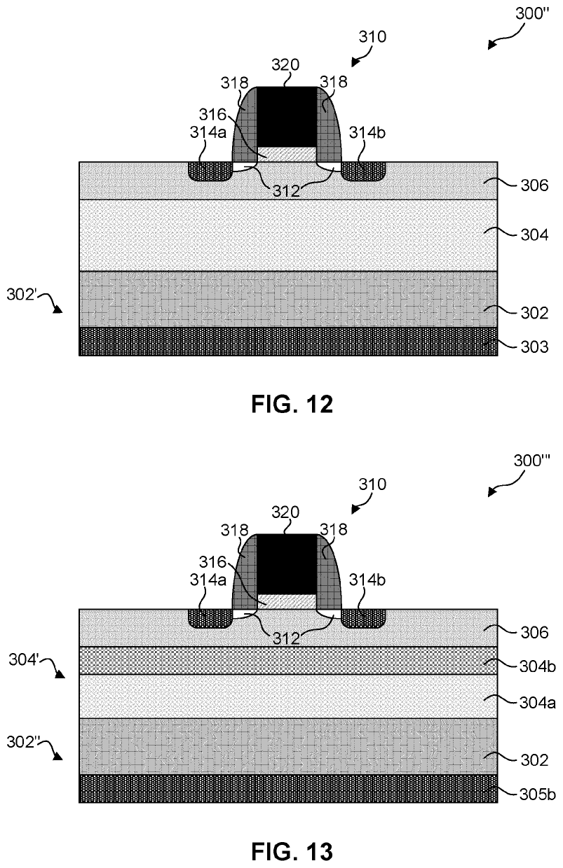

The aspects of porous layered structures 300″ shown in FIG. 12, for example, and the aspects of porous layered structure 300″′ shown in FIG. 13 may be similar. Similar reference numbers are used to indicate features of the aspects of porous layered structure 300″ shown in FIG. 12 and the similar features of the aspects of porous layered structures 300″′ shown in FIG. 13.

FIG. 13 illustrates porous layered structure 300″′ with modified substrate 302″ formed from epitaxial growth process 700 shown in FIG. 7, according to an exemplary aspect. Porous layered structure 300″′ can be configured to increase a resistivity of porous layer 304′ (e.g., greater than 5,000 Ω·cm) thereby decreasing harmonic losses in semiconductor device 310. Porous layered structure 300′″ can be further configured to provide a seed layer for subsequent epitaxy on porous layer 304′. Although porous layered structure 300″′ is shown in FIG. 13 as a stand-alone apparatus and/or system, aspects of this disclosure can be used with other apparatuses, systems, and/or methods, for example, dual bath porosification system 200′, modified substrate 302″, manufacturing diagram 1700, and/or flow diagram 2100.

As shown in FIG. 13, porous layered structure 300′″ can include modified substrate 302″ with backside conductive layer 305b and porous layer 304′. Porous layer 304′ can include first porous sublayer 304a on substrate 302 and second porous sublayer 304b on first porous sublayer 304a. In some aspects, first porous sublayer 304a has a first porosity and second porous sublayer 304b has a second porosity that is less than the first porosity. For example, first porous sublayer 304a can have a first porosity between about 50% to about 65% and second porous sublayer 304b can have a second porosity between about 20% to about 35%. In some aspects, porous layer 304′ can have a higher resistivity than substrate 302. For example, porous layer 304′ can have a resistivity of about 1,000 Ω·cm and substrate 302 can have a resistivity of about 1 Ω·cm. In some aspects, porous layer 304′ can have a high resistivity (e.g., greater than about 5,000 Ω·cm) thereby decreasing harmonic losses. For example, porous layer 304′ can suppress RF field lines from semiconductor device 310 from penetrating (bleeding) into substrate 302. In some aspects, porous layer 304′ can have a thickness of at least 5 μm. For example, porous layer 304′ can have a thickness of about 10 μm. In some aspects, porous layer 304′ can have a thickness no greater than about 2 μm. For example, porous layer 304′ can have a thickness of about 1 μm. In some aspects, second porous sublayer 304b can have a thickness no greater than about 1 μm. For example, second porous sublayer 304b can have a thickness of about 250 nm.

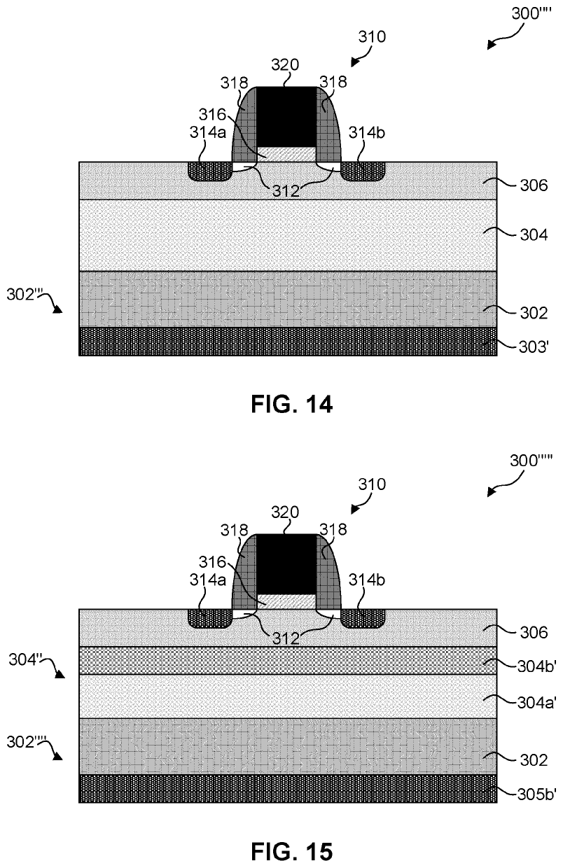

FIG. 14 illustrates porous layered structure 300″″ with modified substrate 302″′ formed from diffusion process 900 shown in FIG. 9, according to an exemplary aspect. Porous layered structure 300″″ can be configured to increase a resistivity of porous layer 304 (e.g., greater than 5,000 £Ω·cm) thereby decreasing harmonic losses in semiconductor device 310. Although porous layered structure 300″″ is shown in FIG. 14 as a stand-alone apparatus and/or system, aspects of this disclosure can be used with other apparatuses, systems, and/or methods, for example, dual bath porosification system 200′, modified substrate 302′, manufacturing diagram 1800, and/or flow diagram 2200.

The aspects of porous layered structure 300″ shown in FIG. 12, for example, and the aspects of porous layered structure 300″″ shown in FIG. 14 may be similar. Similar reference numbers are used to indicate features of the aspects of porous layered structure 300″ shown in FIG. 12 and the similar features of the aspects of porous layered structure 300″″ shown in FIG. 14.

As shown in FIG. 14, porous layered structure 300″″ can include modified substrate 302″′ with backside conductive layer 303′ and porous layer 304. In some aspects, porous layer 304 can have a higher resistivity than substrate 302. For example, porous layer 304 can have a resistivity of about 1,000 Ω·cm and substrate 302 can have a resistivity of about 1 Ω·cm. In some aspects, porous layer 304 can have a high resistivity (e.g., greater than about 5,000 Ω·cm) thereby decreasing harmonic losses. For example, porous layer 304 can suppress RF field lines from semiconductor device 310 from penetrating (bleeding) into substrate 302. In some aspects, porous layer 304 can have a thickness of at least 5 μm. For example, porous layer 304 can have a thickness of about 10 μm.

The aspects of porous layered structures 300″′ shown in FIG. 13, for example, and the aspects of porous layered structure 300″″′ shown in FIG. 15 may be similar. Similar reference numbers are used to indicate features of the aspects of porous layered structure 300″′ shown in FIG. 13 and the similar features of the aspects of porous layered structures 300″″′ shown in FIG. 15.

FIG. 15 illustrates porous layered structure 300″″′ with modified substrate 302″″ formed from diffusion process 1000 shown in FIG. 10, according to an exemplary aspect. Porous layered structure 300″″′ can be configured to increase a resistivity of porous layer 304″ (e.g., greater than 5,000 Ω·cm) thereby decreasing harmonic losses in semiconductor device 310. Porous layered structure 300″″′ can be further configured to provide a seed layer for subsequent epitaxy on porous layer 304″. Although porous layered structure 300″″′ is shown in FIG. 15 as a stand-alone apparatus and/or system, aspects of this disclosure can be used with other apparatuses, systems, and/or methods, for example, dual bath porosification system 200′, modified substrate 302″, manufacturing diagram 1900, and/or flow diagram 2300.

As shown in FIG. 15, porous layered structure 300′″″ can include modified substrate 302″″ with backside conductive layer 305b′ and porous layer 304″. Porous layer 304″ can include first porous sublayer 304a′ on substrate 302 and second porous sublayer 304b′ on first porous sublayer 304a'. In some aspects, first porous sublayer 304a′ has a first porosity and second porous sublayer 304b′ has a second porosity that is less than the first porosity. For example, first porous sublayer 304a′ can have a first porosity between about 50% to about 65% and second porous sublayer 304b′ can have a second porosity between about 20% to about 35%. In some aspects, porous layer 304″ can have a higher resistivity than substrate 302. For example, porous layer 304″ can have a resistivity of about 1,000 Ω·cm and substrate 302 can have a resistivity of about 1 Ω·cm. In some aspects, porous layer 304″ can have a high resistivity (e.g., greater than about 5,000 Ω·cm) thereby decreasing harmonic losses. For example, porous layer 304″ can suppress RF field lines from semiconductor device 310 from penetrating (bleeding) into substrate 302. In some aspects, porous layer 304″ can have a thickness of at least 5 μm. For example, porous layer 304″ can have a thickness of about 10 μm. In some aspects, second porous sublayer 304b′ can have a thickness no greater than about 1 μm. For example, second porous sublayer 304b′ can have a thickness of about 250 nm.

### Exemplary Manufacturing Diagrams

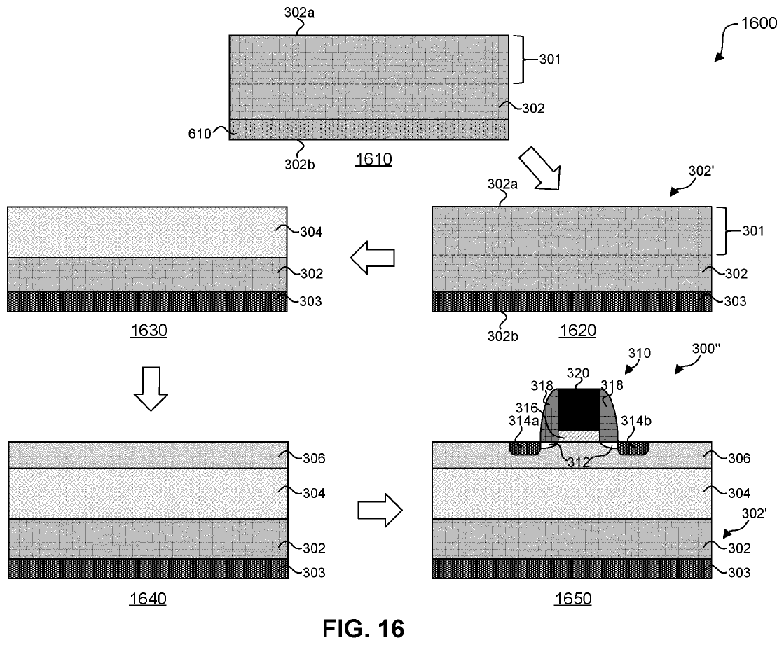

FIG. 16 illustrates manufacturing diagram 1600 for forming porous layered structure 300″, according to an exemplary aspect. It is to be appreciated that not all steps in FIG. 16 are needed to perform the disclosure provided herein. Further, some of the steps can be performed simultaneously, sequentially, and/or in a different order than shown in FIG. 16. Manufacturing diagram 1600 shall be described with reference to FIGS. 5, 6, and 12. However, manufacturing diagram 1600 is not limited to those example aspects.

As shown in FIG. 16, manufacturing diagram 1600 is configured to form porous layered structure 300″ shown in FIG. 12. In step 1610, high dose dopant implants 610 (e.g., B) are implanted into a backside 302b of a substrate 302 having a frontside 302a and a backside 302b by ion implanting. In some aspects, substrate 302 can include any suitable substrate having a predetermined crystallographic orientation, including but not limited to silicon, germanium, gallium nitride (GaN), and III-V semiconductors. In some aspects, high dose dopant implants 610 can include a p-type dopant (e.g., B). In some aspects, high dose dopant implants 610 can include an n-type dopant (e.g., P).

In step 1620, a backside conductive layer 303 is formed in backside 302b of substrate 302 by annealing substrate 302 to diffuse and electrically activate the high dose dopant implants 610, recrystallize backside 302b of substrate 302, and form modified substrate 302′. In some aspects, backside conductive layer 303 can be formed by ion implantation process 600 shown in FIG. 6.

In step 1630, a portion 301 of modified substrate 302′ is porosified from frontside 302a towards backside 302b to form porous layer 304. In some aspects, modified substrate 302′ can be porosified using dual bath porosification system 200′ shown in FIG. 5. In some aspects, manufacturing diagram 1600 can further include annealing porous layer 304 after step 1630 but prior to step 1640. For example, porous layer 304 can be annealed at a temperature between about 300° C. to about 500° C.

In step 1640, an epilayer 306 is grown over porous layer 304 (e.g., on frontside). In some aspects, epilayer 306 can include any suitable epilayer having a predetermined crystallographic orientation, including but not limited to silicon, germanium, gallium nitride (GaN), and III-V semiconductors. In some aspects, epilayer 306 can be a defect-free, single crystal epilayer formed directly atop porous layer 304.

In step 1650, a semiconductor device 310 is formed in epilayer 306 to form porous layered structure 300″. In some aspects, semiconductor device 310 can be a transistor (e.g., MOSFET) in a CMOS device, for example, an RF switch (e.g., RF switch 412 shown in FIG. 4). In some aspects, porous layered structure 300″ can omit semiconductor device 310 in epilayer 306, for example, as shown in step 1640 of FIG. 16. In some aspects, porous layered structure 300″ can omit epilayer 306 over porous layer 304, for example, as shown in step 1630 of FIG. 16.

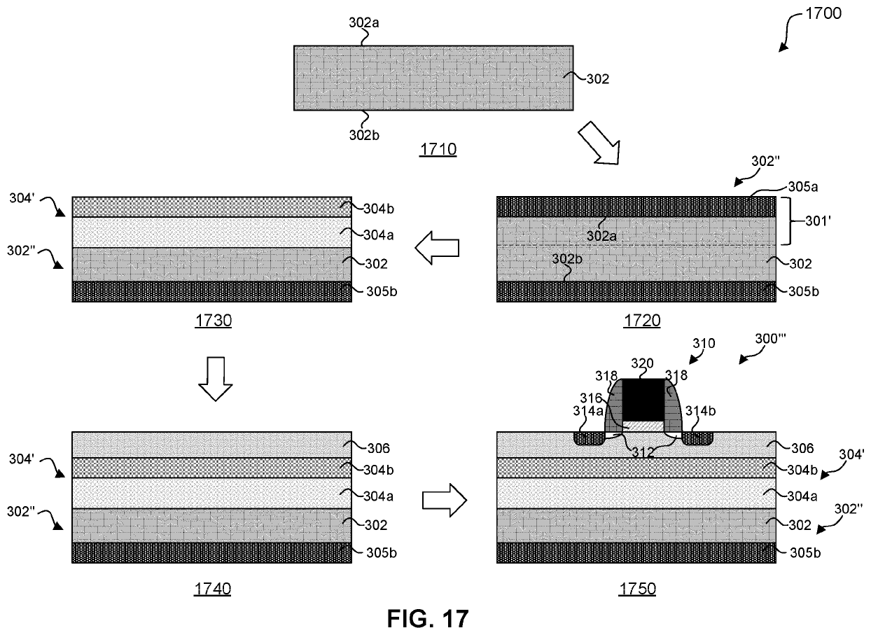

FIG. 17 illustrates manufacturing diagram 1700 for forming porous layered structure 300″, according to an exemplary aspect. It is to be appreciated that not all steps in FIG. 17 are needed to perform the disclosure provided herein. Further, some of the steps can be performed simultaneously, sequentially, and/or in a different order than shown in FIG. 17. Manufacturing diagram 1700 shall be described with reference to FIGS. 5, 7, 8, and 13. However, manufacturing diagram 1700 is not limited to those example aspects.

As shown in FIG. 17, manufacturing diagram 1700 is configured to form porous layered structure 300″′ shown in FIG. 13. In step 1710, a substrate 302 having a frontside 302a and a backside 302b is selected. In some aspects, substrate 302 can include any suitable substrate having a predetermined crystallographic orientation, including but not limited to silicon, germanium, gallium nitride (GaN), and III-V semiconductors.

In step 1720, frontside and backside conductive layers 305a, 305b are formed on frontside 302a and backside 302b of substrate 302 by epitaxy to form modified substrate 302″. In some aspects, frontside and backside conductive layers 305a, 305b can be formed by epitaxial growth process 700 shown in FIG. 7. In some aspects, frontside and backside conductive layers 305a, 305b can be formed by batch process 800 shown in FIG. 8.

In step 1730, a portion 301′ of modified substrate 302″, including all of frontside conductive layer 305a and an upper portion of substrate 302, is porosified from frontside 302a towards backside 302b to form porous layer 304′ with first and second porous sublayers 304a, 304b. In some aspects, modified substrate 302″ can be porosified using dual bath porosification system 200′ shown in FIG. 5. In some aspects, manufacturing diagram 1700 can further include annealing porous layer 304′ after step 1730 but prior to step 1740. For example, porous layer 304′ can be annealed at a temperature between about 300° C. to about 500° C.

In step 1740, an epilayer 306 is grown over porous layer 304′ (e.g., on second porous sublayer 304b). In some aspects, epilayer 306 can include any suitable epilayer having a predetermined crystallographic orientation, including but not limited to silicon, germanium, gallium nitride, and III-V semiconductors. In some aspects, epilayer 306 can be a defect-free, single crystal epilayer formed directly atop porous layer 304′.

In step 1750, a semiconductor device 310 is formed in epilayer 306 to form porous layered structure 300″′. In some aspects, semiconductor device 310 can be a transistor (e.g., MOSFET) in a CMOS device, for example, an RF switch (e.g., RF switch 412 shown in FIG. 4). In some aspects, porous layered structure 300″′ can omit semiconductor device 310 in epilayer 306, for example, as shown in step 1740 of FIG. 17. In some aspects, porous layered structure 300′″ can omit epilayer 306 over porous layer 304′, for example, as shown in step 1730 of FIG. 17.

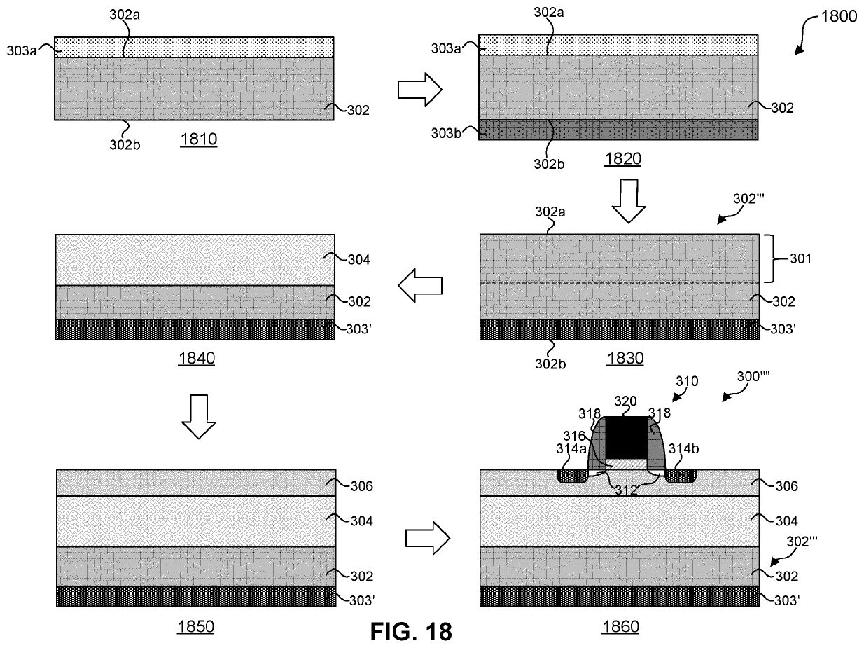

FIG. 18 illustrates manufacturing diagram 1800 for forming porous layered structure 300″″, according to an exemplary aspect. It is to be appreciated that not all steps in FIG. 18 are needed to perform the disclosure provided herein. Further, some of the steps can be performed simultaneously, sequentially, and/or in a different order than shown in FIG. 18. Manufacturing diagram 1800 shall be described with reference to FIGS. 5, 9, and 14. However, manufacturing diagram 1800 is not limited to those example aspects.

As shown in FIG. 18, manufacturing diagram 1800 is configured to form porous layered structure 300″″ shown in FIG. 14. In step 1810, a diffusion blocking layer 303a (e.g., silicon nitride) is formed on a frontside 302a of a substrate 302 having a frontside 302a and a backside 302b. In some aspects, substrate 302 can include any suitable substrate having a predetermined crystallographic orientation, including but not limited to silicon, germanium, gallium nitride (GaN), and III-V semiconductors. In some aspects, diffusion blocking layer 303a can include a nitride or any material sufficient to block diffusion of dopants during an annealing process. For example, diffusion blocking layer 303a can include silicon nitride.

In step 1820, a doped glass layer 303b (e.g., BSG) is formed on backside 302b of substrate 302. In some aspects, doped glass layer 303b can include a p-type dopant. For example, doped glass layer 303b can include BSG with boron dopants. In some aspects, doped glass layer 303b can include a p-type dopant. For example, doped glass layer 303b can include PSG with phosphorus dopants. In some aspects, doped glass layer 303b can be formed by deposition (e.g., CVD).

In step 1830, a backside conductive layer 303′ is formed in backside 302b of substrate 302 by annealing substrate 302 to diffuse and electrically activate dopants (e.g., B) of doped glass layer 303b (e.g., BSG) into substrate 302 to form backside conductive layer 303′ and removing (e.g., etching) diffusion blocking layer 303a and doped glass layer 303b to form modified substrate 302″′. In some aspects, backside conductive layer 303′ can be formed by diffusion process 900 shown in FIG. 9. In some aspects, backside conductive layer 303′ can be formed by batch diffusion process 1100 shown in FIG. 11.

In step 1840, a portion 301 of modified substrate 302″′ is porosified from frontside 302a towards backside 302b to form porous layer 304. In some aspects, modified substrate 302″′ can be porosified using dual bath porosification system 200″′ shown in FIG. 5. In some aspects, manufacturing diagram 1800 can further include annealing porous layer 304 after step 1840 but prior to step 1850. For example, porous layer 304 can be annealed at a temperature between about 300° C. to about 500° C.

In step 1850, an epilayer 306 is grown over porous layer 304 (e.g., on frontside). In some aspects, epilayer 306 can include any suitable epilayer having a predetermined crystallographic orientation, including but not limited to silicon, germanium, gallium nitride, and III-V semiconductors. In some aspects, epilayer 306 can be a defect-free, single crystal epilayer formed directly atop porous layer 304.

In step 1860, a semiconductor device 310 is formed in epilayer 306 to form porous layered structure 300″″. In some aspects, semiconductor device 310 can be a transistor (e.g., MOSFET) in a CMOS device, for example, an RF switch (e.g., RF switch 412 shown in FIG. 4). In some aspects, porous layered structure 300″″ can omit semiconductor device 310 in epilayer 306, for example, as shown in step 1850 of FIG. 18. In some aspects, porous layered structure 300″″ can omit epilayer 306 over porous layer 304, for example, as shown in step 1840 of FIG. 18.

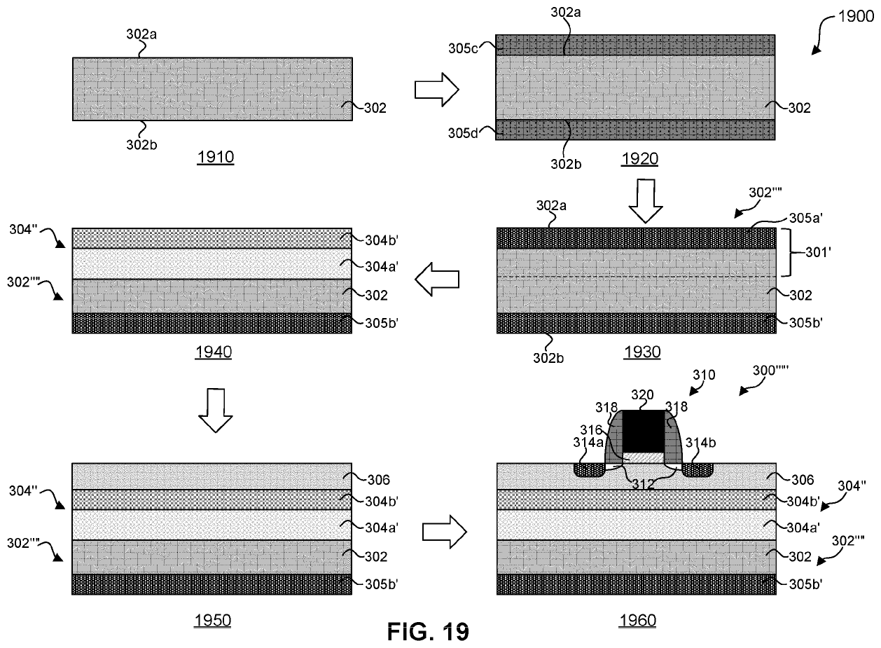

FIG. 19 illustrates manufacturing diagram 1900 for forming porous layered structure 300″″′, according to an exemplary aspect. It is to be appreciated that not all steps in FIG. 19 are needed to perform the disclosure provided herein. Further, some of the steps can be performed simultaneously, sequentially, and/or in a different order than shown in FIG. 19. Manufacturing diagram 1200 shall be described with reference to FIGS. 5, 10, 11, and 15. However, manufacturing diagram 1900 is not limited to those example aspects.

As shown in FIG. 19, manufacturing diagram 1900 is configured to form porous layered structure 300″″′ shown in FIG. 15. In step 1910, a substrate 302 having a frontside 302a and a backside 302b is selected. In some aspects, substrate 302 can include any suitable substrate having a predetermined crystallographic orientation, including but not limited to silicon, germanium, gallium nitride (GaN), and III-V semiconductors.

In step 1920, frontside and backside doped glass layers 305c, 305d (e.g., BSG) are formed on frontside 302a and backside 302b of substrate 302, respectively. In some aspects, frontside and backside doped glass layers 305c, 305d can include a p-type dopant. For example, frontside and backside doped glass layers 305c, 305d can include BSG with boron dopants. In some aspects, frontside and backside doped glass layers 305c, 305d can include a p-type dopant. For example, frontside and backside doped glass layers 305c, 305d can include PSG with phosphorus dopants. In some aspects, frontside and backside doped glass layers 305c, 305d can be formed by deposition (e.g., CVD).

In step 1930, frontside and backside conductive layers 305a′, 305b′ are formed in frontside 302a and backside 302b of substrate 302 by annealing substrate 302 to diffuse and electrically activate dopants (e.g., B) of frontside and backside doped glass layers 305c, 305d (e.g., BSG) into substrate 302 to form frontside and backside conductive layers 305a′, 305b′, respectively, and removing (e.g., etching) frontside and backside doped glass layers 305c, 305d to form modified substrate 302″″. In some aspects, frontside and backside conductive layers 305a′, 305b′ can be formed by diffusion process 1000 shown in FIG. 10. In some aspects, frontside and backside conductive layers 305a′, 305b′ can be formed by batch diffusion process 1100 shown in FIG. 11.

In step 1940, a portion 301′ of modified substrate 302″″, including all of frontside conductive layer 305a′ and an upper portion of substrate 302, is porosified from frontside 302a towards backside 302b to form porous layer 304″ with first and second porous sublayers 304a′, 304b′. In some aspects, modified substrate 302″″ can be porosified using dual bath porosification system 200′ shown in FIG. 5. In some aspects, manufacturing diagram 1900 can further include annealing porous layer 304″ after step 1940 but prior to step 1950. For example, porous layer 304″ can be annealed at a temperature between about 300° C. to about 500° C.

In step 1950, an epilayer 306 is grown over porous layer 304″ (e.g., on second porous sublayer 304b′). In some aspects, epilayer 306 can include any suitable epilayer having a predetermined crystallographic orientation, including but not limited to silicon, germanium, gallium nitride, and III-V semiconductors. In some aspects, epilayer 306 can be a defect-free, single crystal epilayer formed directly atop porous layer 304″.

In step 1960, a semiconductor device 310 is formed in epilayer 306 to form porous layered structure 300″″′. In some aspects, semiconductor device 310 can be a transistor (e.g., MOSFET) in a CMOS device, for example, an RF switch (e.g., RF switch 412 shown in FIG. 4). In some aspects, porous layered structure 300′″″ can omit semiconductor device 310 in epilayer 306, for example, as shown in step 1950 of FIG. 19. In some aspects, porous layered structure 300″″′ can omit epilayer 306 over porous layer 304″, for example, as shown in step 1940 of FIG. 19.

### Exemplary Flow Diagrams

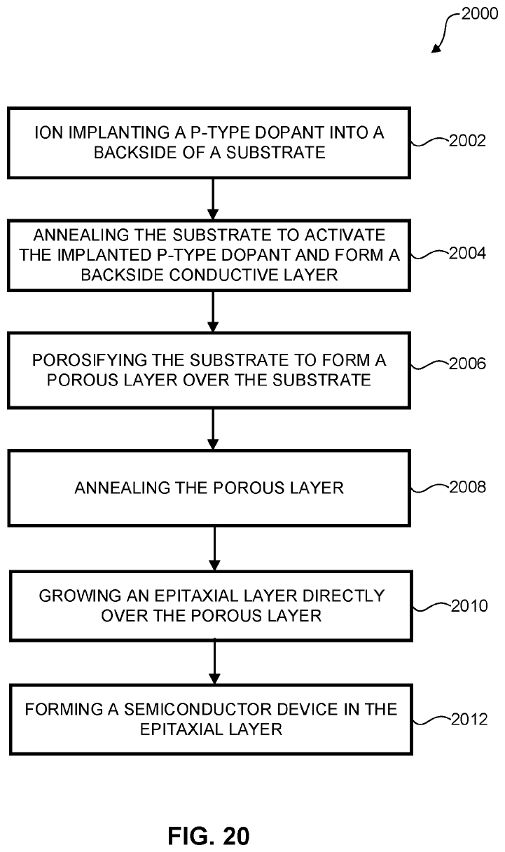

FIG. 20 illustrates flow diagram 2000 to describe the process of forming porous layered structure 300″, according to an exemplary aspect. It is to be appreciated that not all steps in FIG. 20 are needed to perform the disclosure provided herein. Further, some of the steps can be performed simultaneously, sequentially, and/or in a different order than shown in FIG. 20. Flow diagram 2000 shall be described with reference to FIGS. 5, 6, 12, and 16. However, flow diagram 2000 is not limited to those example aspects.

As shown in FIG. 20, flow diagram 2000 describes the process to form porous layered structure 300″ shown in FIG. 12. In step 2002, as shown in the examples of FIGS. 6 and 16, high dose dopant implants 610 (e.g., p-type dopant) are ion implanted into backside 302b of substrate 302. In step 2004, as shown in the examples of FIGS. 6 and 16, substrate 302 with high dose dopant implants 610 (e.g., p-type dopant) is annealed (e.g., temperature of at least 800° C.) to electrically activate high dose dopant implants 610, recrystallize backside 302b of substrate 302, and form modified substrate 302′ with backside conductive layer 303. In some aspects, backside conductive layer 303 can be formed by ion implantation process 600 shown in FIG. 6. In step 2006, as shown in the examples of FIGS. 5 and 16, a portion 301 of modified substrate 302′ is porosified from frontside 302a towards backside 302b to form porous layer 304. In some aspects, flow diagram 2000 can further include exposing porous layer 304 to an acid solution (e.g., HF) after porosifying modified substrate 302′. In step 2008, porous layer 304 is annealed. In some aspects, flow diagram 2000 can omit step 2008. In step 2010, as shown in the example of FIG. 16, an epilayer 306 is grown over porous layer 304 (e.g., on frontside). In step 2012, as shown in the example of FIG. 16, a semiconductor device 310 is formed in epilayer 306 to form porous layered structure 300″.

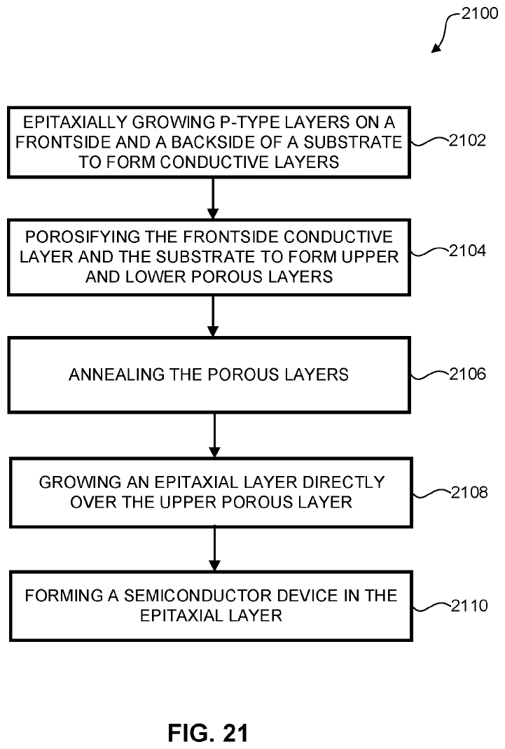

FIG. 21 illustrates flow diagram 2100 to describe the process of forming porous layered structure 300′″, according to an exemplary aspect. It is to be appreciated that not all steps in FIG. 21 are needed to perform the disclosure provided herein. Further, some of the steps can be performed simultaneously, sequentially, and/or in a different order than shown in FIG. 21. Flow diagram 2100 shall be described with reference to FIGS. 5, 7, 8, 10, and 17. However, flow diagram 2100 is not limited to those example aspects.

As shown in FIG. 21, flow diagram 2100 describes the process to form porous layered structure 300″′ shown in FIG. 13. In step 2102, as shown in the examples of FIGS. 7, 8, and 17, frontside and backside conductive layers 305a, 305b are formed on frontside 302a and backside 302b of substrate 302 by epitaxy to form modified substrate 302″. In some aspects, frontside and backside conductive layers 305a, 305b can be formed by epitaxial growth process 700 shown in FIG. 7. In some aspects, frontside and backside conductive layers 305a, 305b can be formed by batch process 800 shown in FIG. 8. In step 2104, as shown in the examples of FIGS. 5 and 17, a portion 301′ of modified substrate 302″, including all of frontside conductive layer 305a and an upper portion of substrate 302, is porosified from frontside 302a towards backside 302b to form porous layer 304′ with first and second porous sublayers 304a, 304b. In some aspects, flow diagram 2100 can further include exposing porous layer 304′ to an acid solution (e.g., HF) after porosifying modified substrate 302″. In step 2106, porous layer 304′ is annealed. In some aspects, flow diagram 2100 can omit step 2106. In step 2108, as shown in the example of FIG. 17, an epilayer 306 is grown over porous layer 304′ (e.g., on second porous sublayer 304b). In step 2110, as shown in the example of FIG. 17, a semiconductor device 310 is formed in epilayer 306 to form porous layered structure 300″′.

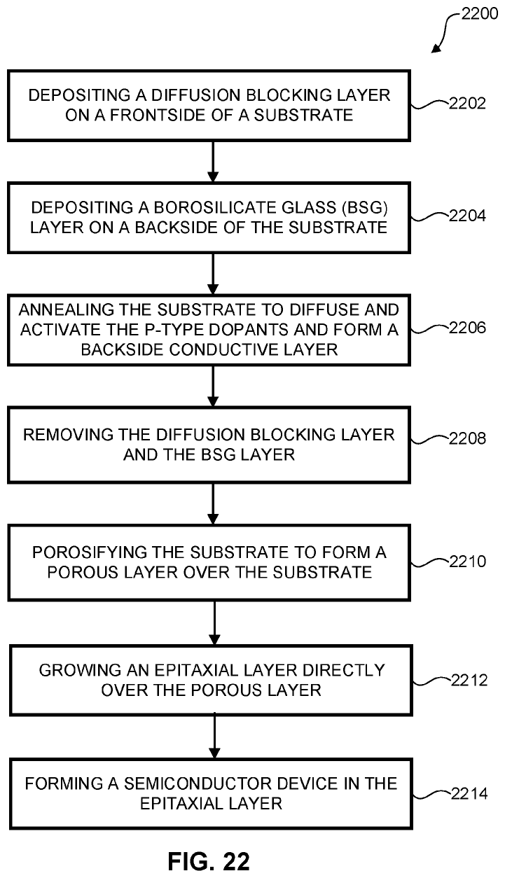

FIG. 22 illustrates flow diagram 2200 to describe the process of forming porous layered structure 300″″, according to an exemplary aspect. It is to be appreciated that not all steps in FIG. 22 are needed to perform the disclosure provided herein. Further, some of the steps can be performed simultaneously, sequentially, and/or in a different order than shown in FIG. 22. Flow diagram 2200 shall be described with reference to FIGS. 5, 9, 14, and 18. However, flow diagram 2200 is not limited to those example aspects.

As shown in FIG. 22, flow diagram 2200 describes the process to form porous layered structure 300″″ shown in FIG. 14. In step 2202, as shown in the examples of FIGS. 9 and 18, diffusion blocking layer 303a (e.g., silicon nitride) is formed on frontside 302a of substrate 302. In step 2204, as shown in the examples of FIGS. 9 and 18, doped glass layer 303b (e.g., BSG) is formed on backside 302b of substrate 302. In step 2206, as shown in the examples of FIGS. 9 and 18, backside conductive layer 303′ is formed in backside 302b of substrate 302 by annealing substrate 302 to diffuse and electrically activate dopants (e.g., B) of doped glass layer 303b (e.g., BSG) into substrate 302 to form backside conductive layer 303′. In some aspects, backside conductive layer 303′ can be formed by diffusion process 900 shown in FIG. 9. In some aspects, backside conductive layer 303′ can be formed by batch diffusion process 1100 shown in FIG. 11. In step 2208, as shown in the examples of FIGS. 9 and 18, diffusion blocking layer 303a and doped glass layer 303b are removed (e.g., via etching) to form modified substrate 302″′. In step 2210, as shown in the examples of FIGS. 5 and 18, a portion 301 of modified substrate 302″′ is porosified from frontside 302a towards backside 302b to form porous layer 304. In some aspects, flow diagram 2200 can further include exposing porous layer 304 to an acid solution (e.g., HF) after porosifying modified substrate 302′″. In some aspects, porous layer 304 can be annealed after step 2210 but prior to step 2212. In step 2212, as shown in the example of FIG. 18, an epilayer 306 is grown over porous layer 304 (e.g., on frontside). In step 2214, as shown in the example of FIG. 18, a semiconductor device 310 is formed in epilayer 306 to form porous layered structure 300″″.

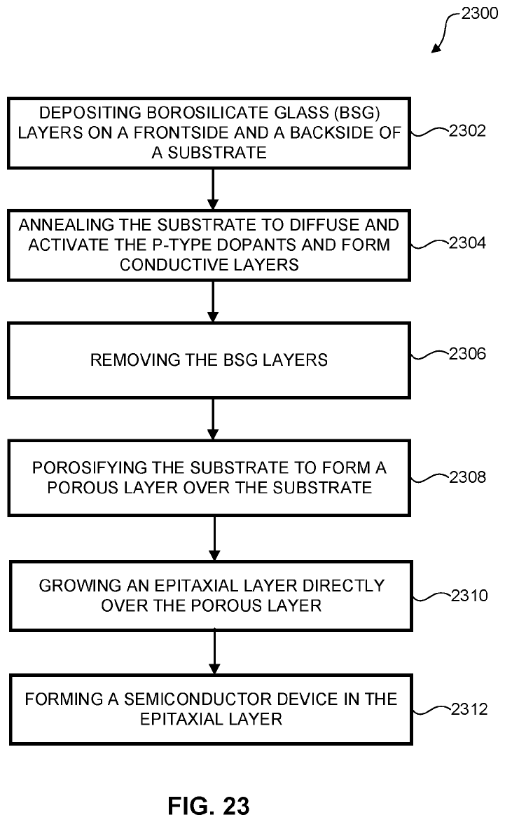

FIG. 23 illustrates flow diagram 2300 to describe the process of forming porous layered structure 300″″′, according to an exemplary aspect. It is to be appreciated that not all steps in FIG. 23 are needed to perform the disclosure provided herein. Further, some of the steps can be performed simultaneously, sequentially, and/or in a different order than shown in FIG. 23. Flow diagram 2300 shall be described with reference to FIGS. 5, 10, 11, 15, and 19. However, flow diagram 2300 is not limited to those example aspects.

As shown in FIG. 23, flow diagram 2300 describes the process to form porous layered structure 300″″′ shown in FIG. 15. In step 2302, as shown in the examples of FIGS. 10 and 19, frontside and backside doped glass layers 305c, 305d (e.g., BSG) are formed on frontside 302a and backside 302b of substrate 302, respectively. In step 2304, as shown in the examples of FIGS. 10 and 19, frontside and backside conductive layers 305a′, 305b′ are formed in frontside 302a and backside 302b of substrate 302 by annealing substrate 302 to diffuse and electrically activate dopants (e.g., B) of frontside and backside doped glass layers 305c, 305d (e.g., BSG) into substrate 302 to form frontside and backside conductive layers 305a′, 305b′, respectively. In some aspects, frontside and backside conductive layers 305a′, 305b′ can be formed by diffusion process 1000 shown in FIG. 10. In some aspects, frontside and backside conductive layers 305a′, 305b′ can be formed by batch diffusion process 1100 shown in FIG. 11. In step 2308, as shown in the examples of FIGS. 10 and 19, frontside and backside doped glass layers 305c, 305d are removed (e.g., via etching) to form modified substrate 302″″. In step 2308, as shown in the examples of FIGS. 5 and 19, a portion 301 of modified substrate 302″″, including all of frontside conductive layer 305a′ and an upper portion of substrate 302, is porosified from frontside 302a towards backside 302b to form porous layer 304″ with first and second porous sublayers 304a′, 304b′. In some aspects, flow diagram 2300 can further include exposing porous layer 304″ to an acid solution (e.g., HF) after porosifying modified substrate 302″″. In some aspects, porous layer 304″ can be annealed after step 2308 but prior to step 2310. In step 2310, as shown in the example of FIG. 18, an epilayer 306 is grown over porous layer 304″ (e.g., on second porous sublayer 304b′). In step 2312, as shown in the example of FIG. 19, a semiconductor device 310 is formed in epilayer 306 to form porous layered structure 300″″′.

It is to be understood that the phraseology or terminology herein is for the purpose of description and not of limitation, such that the terminology or phraseology of the present specification is to be interpreted by those skilled in relevant art(s) in light of the teachings herein.

The following examples are illustrative, but not limiting, of the aspects of this disclosure. Other suitable modifications and adaptations of the variety of conditions and parameters normally encountered in the field, and which would be apparent to those skilled in the relevant art(s), are within the spirit and scope of the disclosure.

While specific aspects have been described above, it will be appreciated that the aspects can be practiced otherwise than as described. The description is not intended to limit the scope of the claims.

The aspects have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects will so fully reveal the general nature of the aspects that others can, by applying knowledge within the skill of the art, readily modify and/or adapt for various applications such specific aspects, without undue experimentation, without departing from the general concept of the aspects. Therefore, such adaptations and modifications are intended to be within the meaning and range of equivalents of the disclosed aspects, based on the teaching and guidance presented herein.

The breadth and scope of the aspects should not be limited by any of the above-described exemplary aspects, but should be defined only in accordance with the following claims and their equivalents.

1. A layered structure comprising:
a non-metal conductive layer coupled to a backside of a substrate, the non-metal conductive layer having a lower resistivity than the substrate; and
a porous layer over the substrate, the porous layer having a higher resistivity than the substrate,
wherein a resistivity of the substrate is between about 0.1 Ω·cm and about 10 Ω·cm.

2. (canceled)

3. The layered structure of claim 1, wherein a resistivity of the substrate is at least about 1 Ω·cm.

4. The layered structure of claim 1, wherein the substrate comprises a Group IV semiconductor or a Group III-V semiconductor.

5. The layered structure of claim 1, wherein a resistivity of the non-metal conductive layer is between about 0.001 Ω·cm and about 0.1 Ω·cm.

6. The layered structure of claim 1, wherein a resistivity of the non-metal conductive layer is no greater than about 0.01 Ω·cm.

7. The layered structure of claim 1, wherein the non-metal conductive layer comprises a p-type dopant concentration of at least about 1×10¹⁷ cm⁻³.

8. The layered structure of claim 1, wherein the non-metal conductive layer comprises heavily doped polycrystalline silicon.

9. The layered structure of claim 1, wherein the porous layer comprises:
a first porous sublayer on the substrate, the first porous sublayer having a first porosity; and
a second porous sublayer on the first porous sublayer, the second porous sublayer having a second porosity that is less than the first porosity.

10. The layered structure of claim 1, further comprising a device on the porous layer or an epitaxial layer grown directly over the porous layer.

11. (canceled)

12. A method comprising:
forming a non-metal conductive layer coupled to a backside of a substrate, the non-metal conductive layer having a lower resistivity than the substrate; and
forming a porous layer over at least a portion of the substrate, the porous layer having a higher resistivity than the substrate,
wherein a resistivity of the substrate is at least about 1 Ω·cm,
wherein a resistivity of the non-metal conductive layer is no greater than about 0.01 Ω·cm, and
wherein a resistivity of the porous layer is at least about 5,000 Ω·cm.

13. (canceled)

14. The method of claim 12, wherein forming the non-metal conductive layer comprises ion implanting a dopant into the backside of the substrate or comprises epitaxially growing a doped layer on the backside of the substrate or comprises diffusing dopants from a doped glass into the backside of the substrate.

15. The method of claim 12, wherein the substrate is a single side polished (SSP) wafer and forming the non-metal conductive layer comprises forming heavily doped polycrystalline silicon.

16. The method of claim 12, further comprising forming a second non-metal conductive layer coupled to a frontside of the substrate, the second non-metal conductive layer having a lower resistivity than the substrate.

17. The method of claim 16, wherein forming the non-metal conductive layer and forming the second non-metal conductive layer comprises simultaneously epitaxially growing doped layers on the backside and the frontside of the substrate.

18. (canceled)

19. The method of claim 16, wherein forming the non-metal conductive layer and forming the second non-metal conductive layer comprises:
simultaneously depositing doped glass layers on the backside and the frontside of the substrate;
annealing the substrate thereby diffusing dopants from the doped glass layers into the substrate; and
removing the doped glass layers.

20. The method of claim 16, further comprising batch processing a plurality of substrates to simultaneously epitaxially grow doped layers on the backside and the frontside of each of the plurality of substrates or simultaneously deposit doped glass layers on the backside and the frontside of each of the plurality of substrates.

21. The method of claim 16, wherein forming the porous layer comprises porosifying the second non-metal conductive layer and an upper portion of the substrate.

22. The method of claim 12, further comprising forming a device on the porous layer or growing an epitaxial layer directly over the porous layer.

23. (canceled)

24. The method of claim 22, further comprising annealing the porous layer prior to growing the epitaxial layer.

25. The method of claim 22, further comprising forming a semiconductor device in the epitaxial layer.
